(19) United States
(12) Patent Application Publication
(10) Pub. No.: US 2003/0054261 A1
(43) Pub. Date: Mar. 20, 2003

(54) Photothermographic material, its processing method, and mask material

(76) Inventor: Takeshi Sampei, Tokyo (JP)

Correspondence Address: BIERMAN MUSERLIAN AND LUCAS, 600 THIRD AVENUE, NEW YORK, NY, 10016

(21) Appl. No.: 10/086,209

(22) Filed: Feb. 28, 2002

(30) Foreign Application Priority Data
Mar. 21, 2001 (JP) 080363/2001

(51) Int. Cl. G03C 1/498; G03C 1/76; G03F 1/12

(52) U.S. Cl. 430/5; 430/620; 430/350; 430/950; 430/627

(57) ABSTRACT

A photothermographic material and its processing method are disclosed, the photothermographic material comprising a support and provided on one side of the support, one or more image forming layers containing a binder, an organic silver salt, silver halide, and a reducing agent, wherein the variation in the maximum surface roughness Rt of the surface on the image forming layer side between the materials before heat treatment and after heat treatment is not more than 1.5 μm.

### FIELD OF THE INVENTION

The present invention relates to a photothermographic material forming an image by thermal development, and an image forming method by use thereof.

### BACKGROUND OF THE INVENTION

In the field of graphic arts and medical treatment, there have been concerns in processing of photographic film with respect to effluents produced from wet-processing of image forming materials, and recently, reduction of the processing effluent is strongly demanded in terms of environmental protection and space saving. There has been desired a photothermographic material for photographic use, capable of forming distinct black images exhibiting high sharpness, enabling efficient exposure by means of a laser imager or a laser image setter. Known as such a technique is a thermally developable photothermographic material which comprises on a support an organic silver salt, silver halide grains, and reducing agent, as described in U.S. Pat. Nos. 3,152,904 and 3,487,075, and D. Morgan, “Dry Silver Photographic Materials” (Handbook of Imaging Materials, Marcel Dekker, Inc. page 48, 1991).

Such a photothermographic material contains a reducible light-insensitive silver source (such as organic silver salts), a light-sensitive silver halide, a reducing agent, and optionally an image color control agent restraining a silver color tone, which are ordinarily dispersed in a binder. The photothermographic materials are stable at ordinary temperature and forms silver upon heating, after exposure, at a relatively high temperature (e.g., 80° C. to 140° C.) through an oxidation-reduction reaction between the reducible silver source (which functions as an oxidizing agent) and the reducing agent. The oxidation reduction reaction is accelerated by catalytic action of a latent image produced by exposure. Silver formed through reaction of the reducible silver salt in exposed areas provides a black image, which contrasts with non-exposes areas, leading to image formation. Such a reaction proceeds without supplying water to the photothermographic materials.

Such photothermographic materials have been mainly employed as photographic materials mainly for use in micrography and medical radiography, but partly for use in graphic arts. This is due to the fact that the photothermographic materials have several problems described below.

1. A photothermographic material is thermally developed and employed as a mask material which is brought into contact with a printing plate material such as a PS plate. The PS plate is brought into contact with the mask material, and exposed through the mask, which is ordinarily repeated several times, and therefore, the mask material has the problem that scratches are likely to occur on the mask surface. Particularly, a photothermographic material is likely to produce scratches on the surface, since it is subjected to thermal treatment at high temperature.

2. Contact of the mask material with a PS plate is poor, resulting in exposure unevenness. Accordingly, when printing is carried out employing a printing plate prepared from the PS plate, there occurred the problems that printed images disappeared or blurred.

3. There is the problem that a photothermographic material is likely to vary its performance and particularly increases fogging during storage.

4. When the developed photothermographic material is employed as a mask material, and fixed with an adhesive tape on a PS plate for imagewise exposure, the adhesive tape is optionally peeled from the mask material and again employed for fixing the mask on the PS plate. There is also the problem that when the mask material is peeled from the mask, image portions of the mask are removed. This is often the case with a photothermographic material comprising an image forming layer containing a polymer latex as a main binder as disclosed in JP-10-69023 or 10-186568.

### SUMMARY OF THE INVENTION

In view of the above, the present invention has been made in order to solve the above problems.

An object of the invention is to provide a photothermographic material minimizing fogging during storage. Another object of the invention is to provide a photothermographic material giving a mask material which is resistant to scratches and does not produce exposure unevenness, when the PS plate is exposed through the mask material. Still another object of the invention is to provide a photothermographic material giving a mask material in which image portions of the mask are difficult to be removed when the mask material is fixed with an adhesive tape on a PS plate and the adhesive tape is peeled from the mask material. Further another object of the invention is to provide an image forming method of forming an image on the photothermographic material described above, and to provide a mask material prepared by exposing the photothermographic material.

### BRIEF EXPLANATION OF THE DRAWINGS

FIG. 1 shows an apparatus for measuring a particle capture efficiency of a filter.

FIG. 2 shows one embodiment of a thermal developing machine used to thermally develop the photothermographic material of the invention.

FIG. 3 shows a side view of a thermal developing machine for comparison.

### DETAILED DESCRIPTION OF THE INVENTION

The object of the invention has been attained by the following constitutions:

1. A photothermographic material comprising a support and provided on one side of the support, one or more image forming layers containing a binder, an organic silver salt, silver halide, and a reducing agent, wherein the variation in the maximum surface roughness Rt of the surface on the image forming layer side between the materials before heat treatment and after heat treatment is not more than 1.5 μm.

2. The photothermographic material of item 1 above, wherein when the material is subjected to heat treatment at 120° C. for 20 seconds, the absolute value of rate of thermal dimensional change in the longitudinal direction and the absolute value of rate of thermal dimensional change in the transverse direction both are from 0.001 to 0.04%.

3. The photothermographic material of item 1 above, wherein at least one layer of the image forming layers contains a latex polymer in an amount of not less than 50% by weight based on the total weight of the binder contained in the at least one layer, and solvents used in coating solutions for coating the image forming layers contain water in an amount of not less than 30% by weight.

4. The photothermographic material of item 1 above, wherein the photothermographic material is subjected to thermal development during which the material is transported while the surface on the image forming layer is brought into contact with rollers driven and the surface of the support opposite the image forming layer is brought into contact with a flat plane.

5. The photothermographic material of item 4 above, wherein the photothermographic material is subjected to thermal development at a transporting speed of from 22 to 40 mm/second.

6. The photothermographic material of item 1 above, wherein at least one layer on the image forming layer side further contains a matting agent of a polymer with a glass transition temperature of not less than 80° C.

7. The photothermographic material of item 6 above, wherein the polymer is a polymer comprising monomer units represented by the following formulae A, B and C:

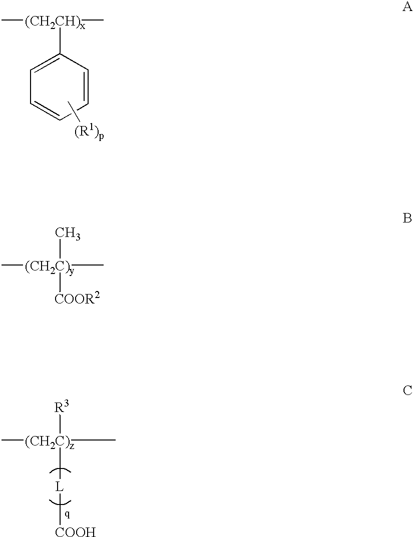

wherein R¹ represents a methyl group or a halogen atom; R² represents a methyl group or an ethyl group; R³ represents a hydrogen atom, a chlorine atom, or a methyl group, L represents a divalent linkage group; p represents an integer of from 0 to 2; q represents 0 or 1; x represents 3 to 60 mol %; y represents 30 to 96.5 mol %; and z represents 0.5 to 25 mol %.

8. The photothermographic material of item 6 above, wherein at least one layer on the image forming layer side is an outermost layer on the image forming layer side.

9. The photothermographic material of item 1 above, wherein at least one layer on the image forming layer side further an inorganic matting agent with an average particle size of from 0.1 to 10 μm.

10. The photothermographic material of item 9 above, wherein at least one layer on the image forming layer side is an outermost layer on the image forming layer side.

11. A method of processing a photothermographic material, the method comprising the step of subjecting the material to thermal development, the material comprising a support and provided on one side of the support, one or more image forming layers containing a binder, an organic silver salt, silver halide, and a reducing agent, wherein the variation in the maximum surface roughness Rt of the surface on the image forming layer side between the materials before heat treatment and after heat treatment is not more than 1.5 μm.

12. The method of item 11 above, wherein when the material is subjected to heat treatment at 120° C. for 20 seconds, the absolute value of rate of thermal dimensional change in the longitudinal direction and the absolute value of rate of thermal dimensional change in the transverse direction both are from 0.001 to 0.04%.

13. The method of item 11 above, wherein at least one layer of the image forming layers of the material contains a latex polymer in an amount of not less than 50% by weight based on the binders contained in the at least one layer, and solvents used in coating solutions for coating the image forming layers contain water in an amount of not less than 30% by weight.

14. The method of item 11 above, wherein the thermal development is one in which the photothermographic material is transported while the surface on the image forming layer is brought into contact with rollers driven and the surface of the support opposite the image forming layers is brought into contact with a flat plane.

15. The method of item 11 above, wherein the thermal development is carried out at a transporting speed of from 22 to 40 mm/second.

16. A mask material prepared by subjecting to thermal development a photothermographic material comprising a support and provided on one side of the support, one or more image forming layers containing a binder, an organic silver salt, silver halide, and a reducing agent, wherein the variation in the maximum surface roughness Rt of the surface on the image forming layer side between the materials before heat treatment and after heat treatment is not more than 1.5 μm.

21. A photothermographic material comprising a support and provided on one side of the support, one or more image forming layers containing an organic silver salt, silver halide, and a reducing agent, wherein the variation in the maximum surface roughness Rt of the surface on the image forming layer side between the materials before thermal developing treatment and after thermal developing treatment is not more than 1.5 μm.

22. The photothermographic material of item 21 above, wherein when the material is subjected to thermal developing treatment at 120° C. for 20 seconds, the absolute value of rate of thermal dimensional change in the longitudinal direction and the absolute value of rate of thermal dimensional change in the transverse direction both are 0.001 to 0.04%.

23. The photothermographic material of item 21 or 22 above, wherein at least one layer of the image forming layers contains a latex polymer in an amount of not less than 50% by weight based on the binders contained in the at least one layer, and solvents used in coating solutions for coating the image forming layers contain water in an amount of not less than 30% by weight.

24. The photothermographic material of any one of items 21 through 23 above, wherein the photothermographic material is subjected to thermal development in which the material is transported while the surface on the image forming layer is brought into contact with rollers driven and the surface of the support opposite the image forming layer is brought into contact with a flat plane.

25. The photothermographic material of any one of items 21 through 24 above, wherein the photothermographic material is subjected to thermal development at a transporting speed of from 22 to 40 mm/second.

26. A method of processing a photothermographic material, the method comprising the step of subjecting the material to thermal development, the material comprising a support and provided on one side of the support, one or more image forming layers containing an organic silver salt, silver halide, and a reducing agent, wherein the variation in the maximum surface roughness Rt of the surface on the image forming layer side between the materials before thermal developing treatment and after thermal developing treatment is not more than 1.5 μm.

27. The method of item 26, wherein when the material is subjected to thermal developing treatment at 120° C. for 20 seconds, the material has an absolute value of rate of thermal dimensional change in the longitudinal direction and the absolute value of rate of thermal dimensional change in the transverse direction both being 0.001 to 0.04%.

28. The method of item 26 or 27 above, wherein at least one layer of the image forming layers of the photothermographic material contains a latex polymer in an amount of not less than 50% by weight based on the binders contained in the at least one layer, and solvents used in coating solutions for coating the image forming layers contain water in an amount of not less than 30% by weight.

29. The method of any one of items 26 through 28 above, wherein the photothermographic material is subjected to thermal development in which the material is transported while the surface on the image forming layer is brought into contact with rollers driven and the surface of the support opposite the image forming layer is brought into contact with a flat plane.

30. The method of any one of items 26 through 29 above, wherein the photothermographic material is subjected to thermal development at a transporting speed of from 22 to 40 mm/second.

31. A mask material prepared by thermally developing the photothermographic material of any one of items 21 through 25 above.

The present invention will be explained in detail below.

The present inventor has made an extensive study on a photothermographic material minimizing fogging during storage, giving a mask material, which is resistant to scratches and does not produce exposure unevenness, when the PS plate is exposed through the mask material, and which improves a peeling strength, and has found that the above problems are solved by limiting to a specific range the variation in the maximum surface roughness Rt of the surface on the image forming layer side between the materials before heat treatment and after heat treatment.

In item 1 above, the photothermographic material is characterized in that the variation in the maximum surface roughness Rt of the surface on the image forming layer side between the materials before heat treatment and after heat treatment is not more than 1.5 μm. The variation is preferably from 0 to 1.2 μm, and more preferably from 0 to 1.0 μm.

The heat treatment herein referred to in the invention means one which preheats a photothermographic material at 115° C. for 15 seconds and then further heats the resulting material at 120° C. for 15 seconds. The variation in the maximum surface roughness Rt of the surface on the image forming layer side between the materials before the heat treatment and after the heat treatment herein referred to means an absolute value of the difference between the maximum surface roughness Rt of the surface on the image forming layer side of the material before the heat treatment and the maximum surface roughness Rt of the surface on the image forming layer side of the material after the heat treatment.

The maximum surface roughness (Rt) herein referred to is defined based on the JIS surface roughness (JIS B0601).

Thus, the maximum surface roughness (Rt) is defined as a value expressed in micrometer (μm), which is obtained by extracting a part of measuring length L from a roughness curve in the direction of its center-line, inserting the roughness curve of the extracted part with two lines parallel with the center-line, and measuring the distance between the two lines.

The maximum surface roughness (Rt) can be determined in such a manner that measuring samples are allowed to stand in an atmosphere of 25° C. and 65% RH over a period of 24 hrs. under the condition that samples are not overlapped and then measured under the same atmosphere. The conditions that samples are not overlapped include a method of taking up in the state of having film edges heightened, a method of overlapping with paper inserted between films and a method of inserting a four-cornered frame of thin paper. Examples of a measurement apparatus include RST/PLUS non-contact type three-dimensional micro surface shape measuring system, available from WYKO Co.

In the photothermographic material of the invention, it is preferred that a surface protective layer be preferably provided on the image forming layer, and it is also preferred that a backing layer be provided on the opposite side of the support to the image forming layer.

The photothermographic material of the invention in which the variation in the maximum surface roughness (Rt) is not more than 1.5 μm can be obtained preferably from an appropriate combination of the techniques described below.

1) a method in which a binder with a glass transition temperature (Tg) of from 75 to 200° C. is contained in at least one image forming layer-protective layer provided on the image forming layer of the photothermographic material.

2) a method in which a matting agent of a polymer with a glass transition temperature of not less than 80° C. is added to at least one layer on the image forming layer side of the photothermographic material.

3) a method in which at least one inorganic matting agent is added to at least one layer on the image forming layer side of the photothermographic material.

4) a method in which after layers on the image forming layer side of the photothermographic material are coated on the support, the coated layers are dried within 7 minutes.

5) A method in which all the coating solutions to be coated on the image forming layer side are filtered before coating at least once employing a filter with an absolute filtration accuracy of from 5 to 50 μm.

6) A method in which the photothermographic material is thermally developed by being transporting while the surface on the image forming layer side contacts a roller driven and the surface of the support opposite the image forming layer contacts a flat plane.

7) A photothermographic material is used, which exhibits an absolute value of rate of thermal dimensional change of 0.001 to 0.04% both in the longitudinal direction and in the traverse direction, after the photothermographic material was subjected to heat treatment at a temperature of 120° C. for 20 sec. The absolute value of rate of thermal dimensional change both in the longitudinal direction and in the traverse direction is preferably 0.005 to 0.03%, and more preferably 0.005 to 0.02%. As the methods to obtain such a photothermographic material, there are, for example, one in which a support subjected to thermal treatment under a low tension is used, one in which a binder with a glass transition temperature of from 75 to 200° C. is used, and one in which layers are coated employing a cross-linking agent to have a three dimensional network structure and to increase Young's modulus or breaking strength of the coated layers.

Each technique described above will be detailed below.

1) a method in which a binder with a glass transition temperature (Tg) of from 75 to 200° C. is contained in at least one image forming layer-protective layer provided on the image forming layer of the photothermographic material.

Binders usable in the image forming layer, the protective layer, a backing layer and a subbing layer are not specifically limited, and for example, any one of a hydrophobic resin and a hydrophilic resin may be used therein in accordance with suitability for each layer.

The hydrophobic resin exhibits advantages such as reduced fogging after thermal development. The preferred examples of the hydrophobic resin binder include polyvinyl butyral resin, cellulose acetate resin, cellulose acetate-butyrate resin, polyester resin, polycarbonate resin, polyacryl resin, polyurethane resin, and polyvinyl chloride resin. Of these, polyvinylbutyral resin, cellulose acetate resin, cellulose acetate-butyrate resin, polyester resin, and polyurethane resin are especially preferred.

Examples of the hydrophilic resin include polyacryl resin, polyester resin, polyurethane resin, polyvinyl chloride resin, polyvinylidene chloride resin, rubber type resin (e.g., SBR resin, NBR resin, etc.), polyvinyl acetate resin, polyolefin resin and polyvinyl acetal resin. The foregoing resins may be a homopolymer obtained by polymerization a single monomer, or a copolymer comprised of two or more kinds of monomers, and may be straight-chained or branched. The resin may be cross-linked.

Such polymers are commercially available, and examples of commercially available acryl resin include Sevian A-4635, 46583, and 4601 (available from DAISEL CHEMICAL Ind. Ltd.), Nipol LX811, 814, 821, 820, and 857 (available from NIHON ZEON Co. Ltd). Examples of polyester rein include FINETEX ES650, 611, 675, 850 (available from DAINIPPON INK CHEMICAL Co. Ltd.), and WD-size WMS (available from Eastman Kodak Corp.). Examples of polyurethane resin include HYDRAN AP10, 20, 30, 40, 101H, HYDRAN HW301, 310, and 350 (available from DAINIPPON INK CHEMICAL Co. Ltd.). Examples of vinylidene chloride resin include L502, L513, L123c, L106c, L111, and L114 (available from ASAHI CHEMICAL IND. Co. Ltd.); examples of vinyl chloride resin include G351 and G576 ((available from NIHON ZEON Co. Ltd.). Examples of olefin resin include CHEMIPAL S-120, S-300, SA-100, A-100, V-100, V-200, and V-300 (available from MITSUI PETROLEUM CHEMICAL IND. Co. Ltd.). Binders used in the invention may be used alone or in a blend.

These resins preferably contain at least one polar group selected from the group consisting of —SO₃M, —OSO₃M, —PO(OM₁)₂ and —OPO(OM₁)₂ (in which M is a hydrogen atom, or an alkali metal such as Na, K or Li, and M₁ is a hydrogen atom, or an alkali metal such as Na, K or Li, or an alkyl group. Of these, —SO₃Na, —SO₃K, —OSO₃Na and —OSO₃K are specifically preferred. The binder resin has a weight average molecular weight of preferably 5000 to 100000, and more preferably 10000 to 50000.

Preferred examples of the binder resin used in the image forming layer include acryl resin, polyvinyl acetal resin, rubber type resin, polyurethane and polyester; and styrene-butadiene resin, polyurethane resin and polyester resin are specifically preferred. The glass transition point (Tg) of the binder resin is preferably 45 to 150° C., and more preferably 60 to 120° C.

As a resin used in the protective layer are preferred cellulose resin, acryl resin and polyurethane. The glass transition point of such resins is preferably 75 to 200° C., and more preferably 100 to 160° C.

Preferred examples of the resin used in the protective layer are shown below, but are not limited thereto.

1) Binder resin A: cellulose acetate butyrate resin with a Tg of 110° C.

2) Binder resin B: polyurethane having a cyclohexane ring containing —SO₃Na (being made from diphenylmethane-diisocyanate/neopentyl glycol/ethylene glycol/cylohexyldimethanol/isophthalic acid/phthalic acid=11/22/3/22/29/13, by weight ratio and exhibiting Tg=73° C.; commercial name UR-8200, product by TOYOCO Co., Ltd.)

3) Binder resin C: acryl resin having —SO₃Na (being made from phenyl methacrylate/4-hydroxyphenyl methacrylamide/4-cyanophenyl methacrylamide=3/4/3, by weight ratio and exhibiting Tg=110° C.)

4) Binder resin D: acryl resin having —SO₃Na (being made from benzyl methacrylate/4-hydroxyphenyl methacrylamide/4-cyanophenyl methacrylamide=3/4/3, by weight ratio and exhibiting Tg=95° C.)

In the photothermographic materials of the invention, the image forming layer contains a polymeric latex (hydrophilic resin) in an amount of preferably at least 50% by weight, more preferably at least 65% and most preferably at least 80% by weight of the total binder contained in the image forming layer. The hydrophilic resin content of at least 50% by weight in the image forming layer leads to advantages such as an improvement in unevenness in density, superior transportability, enhanced manufacturing efficiency and superior friendliness to environments. Further, one feature of using the polymeric latex is the use of an aqueous solvent containing preferably at least 30%, more preferably at least 45%, and most preferably at least 60% by weight of water, as a coating solvent.

2) a method in which a matting agent (hereinafter referred to also as a polymer matting agent) of a polymer with a glass transition temperature of not less than 80° C. is added to at least one layer on the image forming layer side of photothermographic material.

The polymer used in the above polymer matting agent has a glass transition temperature of preferably from 80 to 120° C., and such a polymer has a molecular weight of from 3000 to 1000000, and preferably from 10000 to 100000.

Polymers of the polymer matting agent used in the invention include, for example, a polymer comprising monomer units represented by the following formulae A, B and C:

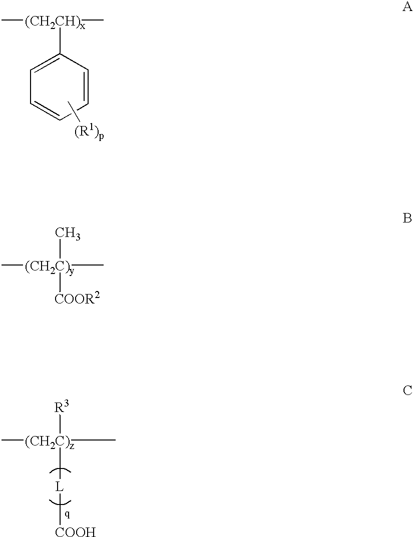

wherein R¹ represents a methyl group or a halogen atom; R² represents a methyl group or an ethyl group; R³ represents a hydrogen atom, a methyl group or a chlorine atom; L represents a divalent linkage group; p represents an integer of from 0 to 2; q represents 0 or 1; x represents 3 to 60 mol %; y represents 30 to 96.5 mol %; and z represents 0.5 to 25 mol %.

In the monomer unit represented by A, R¹ represents a methyl group or a halogen atom, and preferably a methyl group, a chlorine atom or a bromine atom. In the monomer unit represented by B, R² represents a methyl group or an ethyl group. In the monomer unit represented by C, R³ represents a hydrogen atom, a methyl group or a chlorine atom, and L represents a divalent linkage group, and preferably a group represented by the following formula (2).

Formula (2)

—(CO—X¹)r—X²—

In formula (2), X¹ represents an oxygen atom or —NR⁴— in which R⁴ represents a hydrogen atom, or an alkyl group, an aryl group or an acyl group, provided that the alkyl group, aryl group or acyl group may be a substituent (for example, a halogen atom, a nitro group or a hydroxyl group), and preferably a hydrogen atom, an alkyl group having a carbon atom number of 1 to 10 (for example, methyl, ethyl, n-butyl, or n-octyl) or an acyl group (for example, acetyl or benzoyl). The especially preferred X¹ is an oxygen atom or —NH—. r is 0 or 1. X² represents an alkylene group, an arylene group, an alkylene arylene group, or an alkylene arylene alkylene, provided that each may have therein —O—, —S—, —OCO—, —CO—, —COO—, —NH—, —SO₂—, —N(R₅)— or —N(R₅)SO₂— in which R₅ represents a straight chained or branched alkyl group having a carbon atom number of from 1 to 6, for example, methyl, ethyl or iso-propyl. The preferred examples of X² include dimethylene, trimethylene, tetramethylene, o-phenylene, m-phenylene, p-phenylene, —CH₂CH₂OCOCH₂CH₂— or —CH₂CH₂OCOC₆H₄ —.

Examples of the unsaturated carboxylic acid, from which the monomer unit C contained in the polymer is derived, include acrylic acid, methacrylic acid, CH₂=CHCONHCH₂CH₂COOH, CH₂=CHCOOCH₂CH₂COOH, CH₂=CHC₆H₅COOH (p), CH₂=CCH₃CONHCH₂CH₂CH₂COOH, CH₂=CCH₃COOC₆H₅COOH (p), CH₂=CCH₃CONHCH₂CH₂CH₂OCOC₆H₅COOH (p), CH₂=CHCOOCH₂CH₂OCOC₆H₅COOH (o), CH₂=CCH₃COOCH₂CH₂OCOC₆H₅COOH (o), CH₂=CHCONHC₆H₅COOH (o), CH₂=CHCOOCH₂CH₂OCOCH₂CH₂COOH, CH₂=CCH₃CONHC₆H₅COOH (p), CH₂=CCH₃COOCH₂CH₂OCOCH₂CH₂COOH, or α-chloroacrylic acid. Of these, acrylic acid or methacrylic acid is especially preferable.

The monomers, from which the monomer units A, B and C contained in the polymer above are derived, represent ethylenically unsaturated monomers, and do not have two or more double bonds. The polymer can comprise monomer units other than the monomer unit A, B or C, and examples of the monomers, from which the monomer units other than the monomer unit A, B or C are derived, will be listed below.

Examples of acrylic acid eater include methyl acrylate, ethyl acrylate, n-propyl acrylate, iso-propyl acrylate, n-butyl acrylate, iso-butyl acrylate, sec-butyl acrylate, tert-butyl acrylate, amyl acrylate, hexyl acrylate, 2-ethylhexyl acrylate, octyl acrylate, tert-octyl acrylate, 2-chloroethyl acrylate, 2-bromoethyl acrylate, 4-chlorobutyl acrylate, cyanoethyl acrylate, 2-acetoxyethyl acrylate, dimethylaminoethyl acrylate, benzyl acrylate, methoxybenzyl acrylate, 2-chlorohexyl acrylate, cyclohexyl acrylate, furfuryl acrylate, tetrahydrofurfuryl acrylate, phenyl acrylate, 2-hydroxyethyl acrylate, 5-hydroxypentyl acrylate, 2,2-dimethyl-3-hydroxypropyl acrylate, 2-methoxyethyl acrylate, 3-methoxybutyl acrylate, 2-ethoxyethyl acrylate, 2-iso-propoxyethyl acrylate, 2-butoxyethyl acrylate, 2-(2-methoxyethoxy)ethyl acrylate, 2-(2-butoxyethoxy)ethyl acrylate, ω-methoxypolyethylene glycol acrylate (addition mol number: n=9), 1-bromo-2-methoxyethyl acrylate, and 1,1-dichloro-2-ethoxyethyl acrylate, etc.

Examples of methacrylic acid ester include n-propyl methacrylate, iso-propyl methacrylate, n-butyl methacrylate, iso-butyl methacrylate, sec-butyl methacrylate, tert-butyl methacrylate, amyl methacrylate, hexyl methacrylate, cyclohexyl methacrylate, benzyl methacrylate, chlorobenzyl methacrylate, octyl methacrylate, sulfopropyl methacrylate, N-ethyl-N-phenylaminoethyl methacrylate, 2-(3-phenylpropoxy)ethyl methacrylate, dimethylaminophenoxy methacrylate, furfuryl methacrylate, tetrahydrofurfuryl methacrylate, phenyl methacrylate, cresyl methacrylate, naphthyl methacrylate, 2-hydroxyethyl methacrylate, 4-hydroxybutyl acrylate, triethylene glycol monomethacrylate, dipropylene glycol monomethacrylate, 2-methoxyethyl methacrylate, 3-methoxybutyl methacrylate, 2-acetoxyethyl methacrylate, 2-acetoacetoxyethyl methacrylate, 2-ethoxyethyl methacrylate, 2-iso-propoxyethyl methacrylate, 2-butoxyethyl methacrylate, 2-(2-methoxyethoxy)ethyl methacrylate, 2-(2-butoxyethoxy)ethyl methacrylate, ω-methoxypolyethylene glycol methacrylate (addition mol number: n=6), and allyl methacrylate, etc.

Examples of vinyl ester include vinyl acetate, vinyl propionate, vinyl butyrate, vinyl iso-butyrate, vinyl caproate, vinyl chloroacetate, vinyl methoxy acetate, vinyl methoxyacetate, vinyl benzoate, and vinyl salicylate, etc.

Examples of olefins include dicyclopentadiene, ethylene, propylene, 1-butene, 1-pentene, vinyl chloride, vinylidene chloride, isoprene, chloroprene, butadiene, and 2,3-dimethyl butadiene, etc.

Examples of styrenes include trimethylstyrene, ethylstyrene, iso-propylstyrene, chloromethylstyrene, methoxystyrene, acetoxystyrene, trifluoromethylstyrene, and methyl vinylbenzoate, etc.

Examples of crotonic acid ester derivative include butyl crotonate, and hexyl crotonate, etc.

Examples of itaconic acid diester include dimethyl itaconate, diethyl itaconate, and dibutyl itaconate, etc.

Examples of maleic acid diester include diethyl maleate, dimethyl maleate, and dibutyl maleate, etc.

Examples of fumaric acid diester include diethyl fumarate, dimethyl fumarate, and dibutyl fumarate, etc.

Examples of acrylamide include acrylamide, methyl acrylamide, ethyl acrylamide, propyl acrylamide, butyl acrylamide, tert-butyl acrylamide, cyclohexyl acrylamide, benzyl acrylamide, hydroxymethyl acrylamide, 2-methoxyethyl acrylamide, dimethylaminoethyl acrylamide, phenyl acrylamide, dimethyl acrylamide, diethyl acrylamide, β-cyanoethyl acrylamide, and N-(2-acetoacetoxyethyl) acrylamide, and etc.

Examples of methacrylamide include methacrylamide, methyl methacrylamide, ethyl methacrylamide, propyl methacrylamide, butyl methacrylamide, tert-butyl methacrylamide, cyclohexyl methacrylamide, benzyl methacrylamide, hydroxymethyl methacrylamide, 2-methoxyethyl methacrylamide, dimethylaminoethyl methacrylamide, phenyl methacrylamide, dimethyl methacrylamide, diethyl methacrylamide, β-cyanoethyl methacrylamide, and N-(2-cacetoacetoxyethyl) methacrylamide, and etc.

Examples of the allyl compound include allyl acetate, allyl capronate, allyl laurate, and allyl benzoate, etc. Examples of vinyl ether include methyl vinyl ether, butyl vinyl ether, hexyl vinyl ether, and methoxyethyl vinyl ether, etc.

Examples of vinyl ketone include methyl vinyl ketone, phenyl vinyl ketone, and methoxymethyl vinyl ketone, etc. Examples of vinyl heterocyclic compounds include N-vinyloxazolidone, and N-vinylpyrrolidone, etc. Examples of glycidyl esters include glycidyl acrylate and glycidyl methacrylate, etc. Examples of unsaturated nitriles include acrylonitrile and methacrylonitrile, etc.

“p” represents an integer of from 0 to 2, and q represents 0 or 1. In the invention, the polymer comprising units A, B and C may comprise a monomer unit other than A, B and C. When the content of the monomer unit other than A, B and C in the polymer is w (mol %), w is preferably from 0 to 30 mol %, more preferably from 0 to 25 mol %, and still more preferably from 0 to 20 mol %, provided that w+x+y+z=100 (mol %).

The especially preferred polymer comprising the monomer units A, B and C is a polymer wherein x is from 3 to 40 mol %, y is from 40 to 90 mol %, and z is from 1 to 20 mol %, provided that x+y+z=100 (mol %).

In the invention, solution polymerization is preferable to suspension polymerization, since the former provides sharper particle size distribution sharper than the latter under the same emulsification condition.

The preferred examples of the polymer comprising the monomer units A, B and C will be listed below (the monomer unit composition is shown in terms of mol %), but the present invention is not limited thereto. In the example, St represents styrene, MMA represents methyl methacrylate, EMA represents ethyl methacrylate, MA represents methacrylic acid, and AA represents acrylic acid.

(P-1) St (20) MMA (70) MA (10)

(P-2) St (15) MMA (75) MA (10)

(P-3) St (55) MMA (25) MA (10)

(P-4) St (30) MMA (65) MA (5)

(P-5) St (7) MMA (90) MA (3)

(P-6) St (25) MMA (70) AA (15)

(P-7) St (45) MMA (55) AA (15)

(P-8) St (20) EMA (70) AA (10)

(P-9) St (10) EMA (75) AA (15)

(P-10) St (15) EMA (70) MA (15)

(P-11) St (10) MMA (80) Acryloyloxyethyl-o-phthalic acid (10)

(P-12) St (15) MMA (75) Acryloyloxyethyl succinate (10)

(P-13) St (15) MMA (75) Acryloyloxyethyl succinate (7)

(P-14) Cl-St (15) EMA (70) Acryloyloxyethyl-o-phthalic acid (15)

(P-15) p-CH₃-St (40) EMA (55) Methacryloyloxyethyl succinate (5)

(P-16) p-CH₃-St (10) EMA (80) MMA (15)

(P-17) p-CH₃-St (15) MMA (80) AA (5)

(P-18) Cl-St (15) EMA (70) MMA (15)

(P-19) Cl-St (3) EMA (92) MMA (5)

(P-20) Cl-St (10) MMA (80) AA (10)

(P-21) St (20) MMA (60) MMA (10) EMA (10)

(P-22) St (20) MMA (70) MA (5) Butyl acrylate (5)

(P-23) Cl-St (10) EMA (65) MA (15) St (10)

The polymer matting agent used in the invention can be prepared according to a conventional method, but it is preferred that it is prepared according to the method described in Japanese Patent O.P.I. Publication No. 9-208773. Coefficient of variation of the particle size of the matting agent particles, which is represented by the following formula, is ordinarily from 3 to 70%, and preferably from 8 to 55%.

Coefficient of variation of particle size=(Standard deviation of particle size)×100/(Average particle size)

The polymer matting agent is preferably added to at least one of the image forming layer, and an image forming layer-protective layer (which may be an outermost layer on the image forming layer side), but it is especially preferred that the polymer matting agent is added to the outermost layer on the image forming layer side. The added amount of the polymer matting agent in the layer containing the agent is the same as the conventional one, but it is preferably from 0.001 to 0.3 g/m², and more preferably from 0.01 to 0.15 g/m². The average particle size of the polymer matting agent particles is preferably from 0.1 to 10 μm, more preferably from 0.5 to 7 μm, and still more preferably from 1 to 5 μm. The polymer matting agent may be used as a mixture of two or more kinds thereof.

In the invention, when the image forming layer contains a polymer latex as a main binder, the polymer matting agent having a glass transition temperature of not less than 80° C. as described above is effectively used.

3) a method in which at least one inorganic matting agent is added to at least one layer on the image forming layer side of the photothermographic material.

It is preferred in the invention that at least one of the image forming layer and an image forming layer-protective layer (which may be an outermost layer on the image forming layer side) contains inorganic matting agent particles. It is especially preferred in the invention that the outermost layer on the image forming layer side contains inorganic matting agent particles.

Examples of the inorganic matting agent include silicon dioxide, titanium dioxide, magnesium dioxide, aluminum oxide, barium sulfate, calcium carbonate, silver chloride or silver bromide desensitized by commonly know methods, glass and diatomaceous earth. Of these, silicon dioxide, titanium dioxide, and aluminum oxide are preferred. The matting agent used may be a mixture of two or more kinds thereof, and may be the polymer matting agent as described above. These can be prepared according to the methods described in U.S. Pat. Nos. 1,260,772, 2,192,241, 3,257,206, 3,370,951, 3,523,022, and 3,769,020.

The average particle size of the inorganic matting agent particles is preferably from 0.1 to 10 μm, more preferably from 0.5 to 7 μm, and still more preferably from 1 to 5 μm. The average particle size of the inorganic matting agent particles or polymer matting agent in the invention can be determined based on equivalent circle diameter electron-microscopically obtained from the particle projected area. Further, coefficient of variation of particle size, which is represented by the following formula, is preferably from 8 to 55%.

Coefficient of variation=(Standard deviation of particle size)×100/(Average particle size)

The added amount of the inorganic matting agent in the layer containing the agent is the same as the conventional one, but it is preferably from 0.001 to 0.3 g/m², and more preferably from 0.01 to 0.15 g/m².

4) a method in which after layers on the image forming layer side of the photothermographic material are coated on the support, the coated layers are dried within 7 minutes.

As a coating method of the layers of the photothermographic material of the invention, there is a sequential multilayer coating method repeating coating and drying every layer in which a roll coater such as a reverse roll coater or a gravure roll coater, a blade coater, a wire bar coater, or a die coater is used. There is further a simultaneous multiplayer coating method in which another coating solution is coated on a coated layer before drying through plural coaters and the resulting plural layers are dried simultaneously or plural coating solutions are simultaneously coated through a slide coater, a curtain coater, or an extrusion die coater having plural slits. The latter coating method is preferable in preventing coating fault from occurring due to foreign materials from outsides. In order to minimize mixing of different coating layers in the simultaneous multiplayer coating method, a coating solution of an outermost layer has a viscosity of preferably not less than 0.1 Pa.s, and coating solutions of layers other than the outermost layer have a viscosity of preferably not less than 0.03 Pa.s. When coating solutions for adjacent layers are double coated in a wet state, and solid components contained in one coating solution are insoluble or sparingly soluble in an organic solvent of another coating solution, the solid components are crystallized at a boundary between the adjacent layers, resulting in coating defects such as coating fault or cloudiness. In order to minimize such defects, a solvent contained in the largest amount in each coating solution (a solvent contained in common in each coating solution having a content higher than that of another solvent) is preferably the same.

After the simultaneous multiplayer coating, the coated layer is dried preferably as soon as possible. It is preferred that the coated multi-layers arrive at a drying process within ten minutes in order to avoid mixing of the layers due to migration, diffusion or density difference between the coating solutions.

Regarding the drying method, a hot air drying method or an infrared ray drying method, is used, and the hot air drying method is preferred. It is preferred that drying is carried out for not more than 7 minutes employing a hot air of from 30 to 100° C.

5) A method in which all the coating solutions to be coated on the image forming layer side are filtered before coating at least once employing a filter with an absolute filtration accuracy of from 5 to 50 μm.

It is preferred that all the coating solutions used in the preparation of the photothermographic material of the invention are filtered before coating, and are filtered before coating at least once employing a filter with an absolute filtration accuracy of preferably from 5 to 50 μm.

(Absolute filtration accuracy)

Absolute filtration accuracy herein referred to is defined as follows:

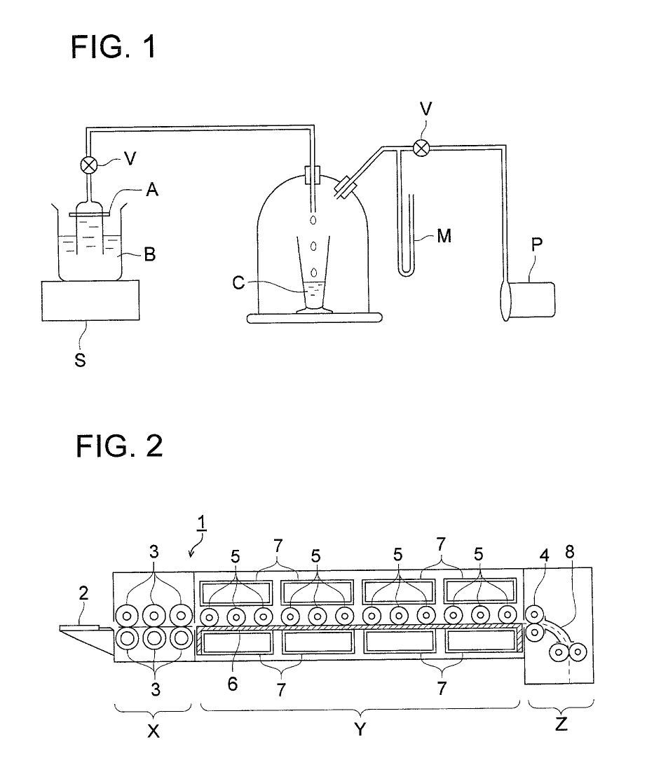

The glass particles as powder for test sample defined in JIS Z 8901 and pure water are placed in a beaker to obtain a liquid, and the liquid is suction filtered while stirring with a stirrer S employing an apparatus as shown in FIG. 1. In FIG. 1, “S” represents a filter for test, B represents a mixture liquid, and C represents a filtrate. The mixture liquid is stirred with a stirrer S, and filtration is carried out while maintaining at a pressure 3.99 kPa lower than atmospheric pressure by a low pressure vacuum pump P. V represents a valve, and M represents a monometer. The number of glass particles in the mixture liquid and the number of glass particles in the filtrate are counted employing a microscope, and rate of particle capture is determined by the formula described later. The particle size providing a rate of particle capture of 95% is defined as an absolute filtration accuracy.

Rate of particle capture=(the number of glass particles in the mixture liquid−the number of glass particles in the filtrate)×100 / the number of glass particles in the mixture liquid

The filter is divided into two types due to its structure, a membrane type or a roll type. The filter of membrane type has, in a filter medium, pores with a specific size and a specific pore size distribution. When several filters of this type with the same pore size and the same pore size distribution are superposed, the resulting filter forms a filter of membrane type and surface type. When several filters are wound on a core to be a thickness of from 10 to 20 mm so that the pore size of a filter on the core side is less than those on the outer side, the resulting filter forms a filter of membrane type and depth type.

Examples of the filter of membrane type include a membrane cartridge filter TCF TYPE or and a pleat cartridge filter TCPE TYPE each produced by Advantec Toyo Co., Ltd.

The filter of roll type is one in which a filter medium having voids with a specific size, for example, an untwisted polypropylene lint is wound around a core with a specific density. The filter wound around a core with no density inclination forms a filter of surface type, and the filter wound around a core with the void size variation or the density inclination forms a filter of depth type. Examples of the filter of roll type include a wind cartridge filter TCW TYPE produced by Advantec Toyo Co., Ltd. The core herein referred to is a hollow core for winding a lint or a membrane of a filter medium.

The filtration employing these filters is preferably carried out several times, since undesired aggregates are effectively removed. Filtration is carried out preferably 3 to 10 times, since too many filtrations are not so effective in proportion to the process number.

Immediately after coating and drying, the photothermographic material of the invention may be cut into an intended size and packaged, or may be wound in a roll form and temporarily stored before cutting or packaging. The winding method is not limited, but winding is generally carried out controlling a tension applied to the material.

6) A method in which the photothermographic material is thermally developed by being transporting while the surface on the image forming layer side contacts a roller driven and the surface of the support opposite the image forming layer contacts a flat plane.

In the photothermographic material of the invention, the imagewise exposed photothermographic material is usually heated to develop. The developing temperature is preferably from 80 to 250° C., and more preferably from 100 to 140° C. The heat-developing time is preferably 1 to 180 sec., and more preferably 10 to 90 sec.

As a method to minimize uneven development due to dimensional change of the photothermographic material occurring during thermal development, a method, so-called a multi stage heating method, is effective in which the photothermographic material is preliminarily heated at 80 to less than 115° C. (preferably not more than 113° C.) for not more than 5 seconds, and then thermally developed at not less than 110° C. (preferably not more than 130° C.) to form an image.

In order to attain the object of the invention, a thermal developing processor (a thermal developing machine) is preferably used in which the photothermographic material is thermally developed by being transporting while the surface on the image forming layer side contacts a roller driven and the surface of the support opposite the image forming layer contacts a flat plane.

FIG. 2 represents one embodiment of a thermal developing machine used to thermally develop the photothermographic material of the invention. In FIG. 2, the thermal developing machine 1 represents a side view of the thermal developing machine. The thermal developing machine 1 has a pair of introducing rollers 3 (the lower one being a heated roller) transporting the photothermographic material 2, while maintaining it planar and preheating it, to a thermal development section, and a pair of discharging rollers 4 discharging from the thermal development section the photothermographic material 2 after thermal development while maintaining it planar. The photothermographic material 2 is subjected to thermal development while it is transported from the introducing rollers 3 to the discharging rollers 4. The transporting means, by which the photothermographic material 2 is transported during thermal development, comprises plural rollers 5 provided on the first surface side on the image forming layer side, the first surface contacting the rollers, and a flat plane 6 made of a laminate of unwoven fabric etc. provided on the second surface side (hereinafter referred to also as back surface side) of the support opposite the image forming layer, the second surface contacting the flat plane. The photothermographic material 2 is transported by driving the plural rollers 5, being inserted between the plural rollers 5 contacting the surface on the image forming layer side and the flat plane 6 contacting the back surface. As a heating means, heaters 7 are provided above the rollers 5 and beneath the flat plane 6 to heat the photothermographic material 2 from the both surface sides. The heating means include a plate heater. The clearance between the rollers 5 and the flat plane 6 is suitably adjusted to the clearance capable of transporting the photothermographic material 2 although it is different due to materials of the flat plane. The clearance is preferably 0 to 1 mm.

Material of the surface of the rollers 5 or material of the flat plate 6 may be any as long as it has durability to high temperature and do not produce any problems in transporting the photothermographic material. However, it is preferred that material of the surface of the rollers 5 is a silicon rubber and material of the flat plate is an unwoven cloth made of polyphenylene sulfite (PPS) or teflon (PTFE). As the heating means, plural heaters are used, and it is preferred that heating temperatures at the heaters are independently set.

A heating section is composed of a preliminarily heating section X having a pair of introducing rollers 3 and a thermal development section Y having the heater 7. It is preferred that a heating temperature at the preliminarily heating section X, which is located upstream of the thermal development section Y, is set to a temperature lower than, for example, 10 to 20° C. lower than, that at the thermal development section Y and higher than the glass transition point of the support of the photothermographic material 2 so as not to produce development unevenness. Downstream of the thermal development section Y, a gradually cooling section Z is provided, which comprises a pair of discharging rollers 4 and a guide plate 8. The guide plate is preferably made of material having a low heat conductivity, and it is preferred that gradual cooling is carried out.

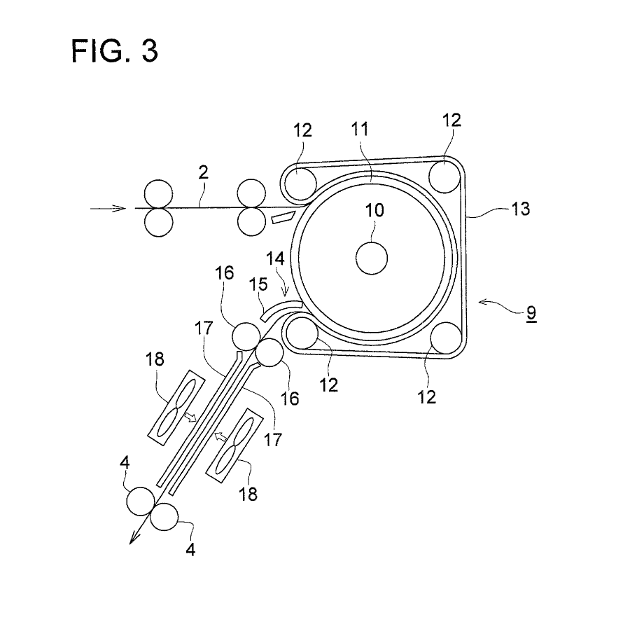

FIG. 3 shows a side view of a thermal developing machine for comparison. This thermal developing machine 9 comprises a heating drum 11 in cylindrical form having an interior, the interior having a heat source, a halogen lamp 10 as a heating means, and an endless belt 13 for transport, which is supported by plural driving rollers 12 and contacts the outer circumferential surface of the heating drum 11. The photothermographic material 2 is inserted between the endless belt 13 and the heating drum 11, and transported. During the transportation, the photothermographic material 2 is heated to a developing temperature, and thermally developed. Thermal development employing the thermal developing machine of drum type is carried out in which irradiation of the lamp is optimized so that the temperature difference in the transverse direction of the photothermographic material falls within the range of ±1° C.

A planing guide plate 15 is provided at the outlet 14 at which the photothermographic material 2 to have been developed is discharged from between the heating drum 11 and the endless belt 13. The planing guide roller 15 returns the photothermographic material 2 to be planar, which has been curved to be in accordance with the curvature of the circumferential surface of the heating drum 11. The temperature at the vicinity of the planing guide plate 15 is controlled so that the temperature of the photothermographic material 2 does not fall to not more than 90° C.

A pair of conveying rollers 16, which convey the photothermographic material 2, are provided downstream of the outlet 14. Downstream of the conveying rollers are provided a pair of planar guide plates 17 which are adjacent to the conveying rollers and guide the photothermographic material 2 while maintaining it planar. Downstream of the pair of planar guide plates 17 are provided a pair of discharging rollers 4 which are adjacent to the planar guide plates 17. The planar guide plates 17 have a length enough to cool the photothermographic material 2 when it passes through between the planar plates. That is, the thermally developed photothermographic material 2 is cooled to not more than 30° C. while it passes through between the planar plates. As a cooling means, fans 18 are used.

7) a method in which a photothermographic material is used which exhibits an absolute value of rate of thermal dimensional change of 0.001 to 0.04% both in the longitudinal direction and in the traverse direction, after the photothermographic material has been subjected to heat treatment at a temperature of 120° C. for 20 sec.

The absolute value of rate of thermal dimensional change both in the longitudinal direction and in the traverse direction as described above is preferably 0.001 to 0.04%, more preferably 0.005 to 0.03%, and still more preferably 0.005 to 0.02%.

The methods to obtain a photothermographic material having the above described absolute value of rate of thermal dimensional change include 1) one in which a support subjected to thermal treatment under a low tension is used, 2) one in which a binder with a glass transition temperature of from 75 to 200° C. is used, and 3) one in which layers are coated employing a cross-linking agent to have a three dimensional network structure and to increase Young's modulus or breaking strength of the coated layers.

In the invention, the rate of thermal dimensional change between the photothermographic materials before and after the heat treatment is determined in accordance with the following procedure.

A photothermographic material sample is cut to 12 cm×15 cm and allowed to stand under an atmosphere of 25° C. and 60% RH for at least 4 hours. Paired holes are perforated on the sample at 10 cm intervals, and the distance between the paired holes is measured by a pin-gauge and the obtained value is designated as L1. After the sample being subjected to heat treatment at 120° C. for 20 seconds, it is again allowed to stand under an atmosphere of 25° C. and 60% RH for at least 4 hours. The distance between the paired holes of the resulting sample is measured by a pin-gauge and the obtained value is designated as L2.

The above described value range of the rate of thermal dimensional change can be obtained, for example, from an appropriate combination of the techniques described below.

a) Anneal treatment is applied to a plastic support under a low tension. An appropriate combination of the methods described in, for example, Japanese Patent Publication No. 60-22616, U.S. Pat. No. 2,779,684, RD 19809, and Japanese Patent O.P.I. Publication Nos. 8-211547, 10-10676, 10-10677, 11-47676, 11-65025, 11-138628, 11-138648, 11-221892, 11-333922, and 11-333923, is preferred.

The tension applied to the support during its thermal treatment, preferably during coating of a subbing layer on the support is preferably from 0.39×10⁴ to 7.80×10⁵ Pa (from 0.04 to 8 kg/cm²), more preferably from 1.96×10⁴ to 5.88×10⁵ Pa (from 0.2 to 6 kg/cm²), and still more preferably from 9.80×10⁴ to 4.90×10⁵ Pa (from 1 to 5 kg/cm²).

The thermal treatment temperature or the drying temperature after coating is from 70 to 220° C., preferably from 80 to 200° C., and more preferably from 90 to 190° C. The thermal treatment time or the drying time after coating is preferably from 1 to 30 minutes, more preferably from 2 to 20 minutes, and still more preferably from 3 to 15 minutes.

Examples of plastic resin used as the support include polyalkyl methacrylate (e.g., polymethyl methacrylate), polyesters (e.g., polyethylene terephthalate), polyvinyl acetal, polyamides (e.g., nylon), and cellulose esters (e.g., cellulose nitrate, cellulose acetate, cellulose, acetate-propionate, cellulose acetate-butyrate, etc.). The support may be coated with polymers, including polyvinylidene chloride, acrylic acid type polymers (e.g., polyacrylonitrile, polymethyl acrylate), polymers of unsaturated carboxylic acids (e.g., itaconic acid, acrylic acid), carboxymethyl cellulose and polyacrylamide. Copolymers may also be used. Instead of polymer coating, there may be provided a subbing layer containing a polymer.

b) A support is employed satisfies the relationships

0.9≦X/Y≦1.1, and 0≦|X-Y|≦50,

wherein X (kg/mm²) represents a Young's modulus in the longitudinal (MD) direction of the support used, and Y (kg/mm²) represents a Young's modulus in the transverse (TD) direction of the support used. The polymers constituting such a support include a polymer with a high Tg, for example, a polyester, a polycarbonate, a polyarylate, a polyetherimide, a polysulfone, a polyethersulfone, and a syndiotactic polystyrene. Of these, a polyester, a polycarbonate, and a polyarylate are preferable, and a polyester is especially preferable.

The preferred supports include a plastic support comprising polyethylene terephthalate or styrene type polymer having syndiotactic structure. The support thickness is preferably 50 to 300 μm, and more preferably 70 to 180 μm. There may be used a plastic resin support which has been subjected to a thermal treatment. Plastic resins adopted therein are those described above. As a thermal treatment, the support is preferably heated at a temperature higher than the glass transition temperature of the support by at least 30° C., more preferably at least 35° C., and still more preferably at least 40° C., before being coated with an image forming layer.

c) The solvent composition in the coating solution or the drying condition after coated is controlled so that the residual solvent content of the photothermographic material is preferably from 1 to 50 mg/cm², and more preferably from 5 to 30 mg/cm².

d) The equilibrium moisture content rate of the photothermographic material is controlled to be not more than 2% by weight.

The equilibrium moisture content rate (D) of the photothermographic material is represented by the following formula:

D (%)=(w/W)×100

wherein W represents weight of photothermographic material which is in equilibrium under an atmosphere of 25° C. and 60% RH, and w represents a moisture content by weight of the photothermographic material.

In the invention, the equilibrium moisture content rate (D) of the photothermographic material at an atmosphere of 25° C. and 60% RH is preferably not more than 2% by weight, more preferably from 0.005 to 2% by weight, and still more preferably from 0.01 to 1% by weight. A method of obtaining an equilibrium moisture content rate of not more than 2% by weight is one employing an organic solvent having a solubility in water of not more than 2% by weight in a coating solution. Examples of the organic solvent include benzene, toluene, xylene, hexane, cyclohexane, diethyl ether, diisopropyl ether, hydrofluoroether, methylene chloride, chloroform, and trichloroethylene. The organic solvent having a solubility in water of not more than 2% by weight may be used singly or as a mixture of two or more kinds thereof. Further, the organic solvent may be used in combination with a water miscible organic solvent, provided that the water content of the coating solution is not more than 2% by weight. Another method of obtaining the above equilibrium moisture content rate is one employing a polymer latex employing a water miscible organic solvent and having an equilibrium moisture content rate under an atmosphere of 25° C. and 60% RH of from 0.01 to 2% by weight, and preferably from 0.01 to 1% by weight.

The measurement or the definition of the equilibrium moisture content rate can be referred to one described in, for example, Kobunshikogaku Koza 14, Kobunshizairyo Sikenho (edited by Kobunsi Gakkai, published by Chijinshokan).

Further another method is one in which the photothermographic material is packaged in a water impermeable packaging material in which a moisture removing desiccant is introduced. The moisture removing desiccant may be any as long as moisture is removed in the presence of the desiccant. Examples of the moisture removing desiccant include silica gel, Molecular Sieves, anhydrous magnesium sulfate, anhydrous sodium sulfate, pure iron and an iron compound. The preferred desiccant is silica gel.

The equilibrium moisture content rate is measured according to the following procedure:

The photothermographic material was allowed to stand at 25° C. and 60% RH for 24 hours. The resulting photothermographic material is cut to a size of 46.3 cm² at the same condition as above, and weighed. Subsequently, the photothermographic material is cut to about 5 mm size, placed in a vial, closely sealed with a septum and an aluminum cap, and set in a Head Space Sampler TYPE HP7694 produced by Hewlett-Packard Co., Ltd. The Head Space Sampler is heated at 120° C. for 20 minutes, and the evaporated moisture vapor is measured according to a Karl Fischer technique.

Next, the photothermographic material of the invention will be explained. The photothermographic material of the invention comprises a support, and provided on the one side of the support, one or more image forming layers containing an organic silver salt, silver halide grains, and reducing agent.

Organic Silver Salt

In the invention, organic silver salts are reducible silver source, and silver salts of organic acids or hetero atom-containing organic acids are preferred, and silver salts of long chain fatty acids (having preferably 10 to 30 carbon atom and more preferably 15 to 25 carbon atoms) or silver salts of nitrogen containing heterocyclic compounds are more preferred. Specifically, organic or inorganic complexes, the ligand of which has a total stability constant to a silver ion of 4.0 to 10.0, are preferred. Exemplary preferred complex salts are described in Research Disclosure (hereinafter, also denoted as RD) 17029 and RD29963, including organic acid salts (for example, salts of gallic acid, oxalic acid, behenic acid, stearic acid, palmitic acid, lauric acid, etc.); carboxyalkylthiourea salts (for example, 1-(3-carboxypropyl)thiourea, 1-(3-caroxypropyl)-3,3-dimethylthiourea, etc.); silver complexes of polymer reaction products of aldehyde with hydroxy-substituted aromatic carboxylic acid (for example, aldehydes (formaldehyde, acetaldehyde, butylaldehyde, etc.), hydroxy-substituted acids (for example, salicylic acid, benzoic acid, 3,5-dihydroxybenzoic acid, 5,5-thiodisalicylic acid, silver salts or complexes of thiones (for example, 3-(2-carboxyethyl)-4-hydroxymethyl-4-(thiazoline-2-thione and 3-carboxymethyl-4-thiazoline-2-thione), complexes or salts of silver with a nitrogen containing acid selected from imidazole, pyrazole, urazole, 1.2,4-thiazole, and 1H-tetrazole, 3-amino-5-benzylthio-1,2,4-triazole and benztriazole; silver salts of saccharin, 5-chlorosalicylaldoxime, etc.; and silver salts of mercaptides. Of these organic silver salts, silver behenate, silver arachidate and silver stearate are specifically preferred.

The organic silver salt compound can be obtained by mixing an aqueous-soluble silver compound with a compound capable of forming a complex. Normal precipitation, reverse precipitation, double jet precipitation and controlled double jet precipitation described in JP-A 9-127643 are preferably employed (hereinafter, the term, JP-A refers to unexamined and published Japanese Patent Application). For example, to an organic acid is added an alkali metal hydroxide (e.g., sodium hydroxide, potassium hydroxide, etc.) to form an alkali metal salt soap of the organic acid (e.g., sodium behenate, sodium arachidate, etc.), thereafter, the soap and silver nitrate are mixed by the controlled double jet method to form organic silver salt crystals. In this case, silver halide grains may be concurrently present.

Silver Halide Grain

Silver halide grains in the invention function as a light sensor. In order to minimize cloudiness after image formation and to obtain excellent image quality, the less the average grain size, the more preferred, and the average grain size is preferably not more than 0.01 μm, more preferably from 0.01 to 0.1 μm, and most preferably from 0.02 to 0.08 μm. The average grain size as described herein is defined as an average edge length of silver halide grains, when they are so-called regular crystals in the form of cube or octahedron. Further, when the grains are not regular crystals, for example, spherical, cylindrical, and tabular grains, the grain size refers to the diameter of a sphere having the same volume as the silver grain. Furthermore, silver halide grains are preferably monodisperse grains. The monodisperse grains as described herein refer to grains having a grain size dispersity obtained by the formula described below of not more than 40%. The grain size dispersity is preferably not more than 30%, and more preferably from 0.1 to 20%:

Grain size dispersity (%)=(standard deviation of grain size)×100/(average grain size)

It is preferred in the invention that the silver halide grains used in the invention have an average grain diameter of not more than 0.1 μm and are monodisperse, and such a range of the grain size enhances image graininess.

The silver halide grain shape is not specifically limited, but a high ratio accounted for by a Miller index [100] plane is preferred. This ratio is preferably at least 50%; is more preferably at least 70%, and is most preferably at least 80%. The ratio accounted for by the Miller index [100] face can be obtained based on T. Tani, J. Imaging Sci., 29, 165 (1985) in which adsorption dependency of a [111] face or a [100] face is utilized.

Furthermore, another preferred silver halide shape is a tabular grain. The tabular grain as described herein is a grain having an aspect ratio represented by r/h of at least 3, wherein r represents a grain diameter in μm defined as the square root of the projection area, and h represents thickness in μm in the vertical direction. Of these, the aspect ratio is preferably between 3 and 50. The grain diameter is preferably not more than 0.1 μm, and is more preferably between 0.01 and 0.08 μm. These are described in U.S. Pat. Nos. 5,264,337, 5,314,789, 5,320,958, and others. In the present invention, when these tabular grains are used, image sharpness is further improved.

The composition of silver halide may be any of silver chloride, silver chlorobromide, silver iodochlorobromide, silver bromide, silver iodobromide, or silver iodide. Silver halide emulsions used in the invention can be prepared according to the methods described in P. Glafkides, Chimie Physique Photographique (published by Paul Montel Corp., 19679; G. F. Duffin, Photographic Emulsion Chemistry (published by Focal Press, 1966); V. L. Zelikman et al., Making and Coating of Photographic Emulsion (published by Focal Press, 1964).

In order to improve reciprocity law failure or to adjust cnotrast, silver halide used in the invention preferably occludes ions of metals belonging to Groups 6 to 11 of the Periodic Table. Preferred as the metals are W, Fe, Co, Ni, Cu, Ru, Rh, Pd, Re, Os, Ir, Pt and Au. These metals may be introduced into silver halide in the form of a complex.

Silver halide grain emulsions may be desalted after the grain formation, using the methods known in the art, such as the noodle washing method and flocculation process. However, in the invention, desalting may or may not be carried out.

The photosensitive silver halide grains used in the invention are preferably subjected to a chemical sensitization. As preferable chemical sensitizations, commonly known chemical sensitizations in this art such as a sulfur sensitization, a selenium sensitization and a tellurium sensitization are usable. Furthermore, a noble metal sensitization using gold, platinum, palladium and iridium compounds and a reduction sensitization are available.

In order to minimize haze (or cloudiness) of the photothermographic material, the total silver coverage including silver halide grains and organic silver salts is preferably 0.3 to 2.2 g/m², and more preferably 0.5 to 1.5 g/m². Such a silver coverage forms a relatively high contrast image. The silver halide amount is preferably not more than 50% by weight, and more preferably not more than 25% by weight, and still more preferably 0.1 to 15% by weight, based on the total silver amount.

As spectral sensitizing dyes used in the invention are optionally employed those described in JP-A 63-159841, 60-140335, 63-231437, 63-259651, 63-304242, 63-15245; U.S. Pat. Nos. 4,639,414, 4,740,455, 4,741,966, 4,751,175, and 4,835,096. Further, sensitizing dyes usable in the invention are also described in Research Disclosure item 17643, sect. IV-A, page 23 (December, 1978) and ibid, item 1831, sect. X, page 437 (August, 1978). Sensitizing dyes suitable for spectral characteristics of various scanner light sources are advantageously selected, as described in JP-A 9-34078, 9-54409 and 9-80679.

Reducing Agent

Reducing agents are preferably incorporated into the photothermographic material of the present invention. Examples of suitable reducing agents are described in U.S. Pat. Nos. 3,770,448, 3,773,512, and 3,593,863, and Research Disclosure Items 17029 and 29963, and include the following: aminohydroxycycloalkenone compounds (for example, 2-hydroxypiperidino-2-cyclohexane); esters of amino reductones as the precursor of reducing agents (for example, piperidinohexose reducton monoacetate); N-hydroxyurea derivatives (for example, N-p-methylphenyl-N-hydroxyurea); hydrazones of aldehydes or ketones (for example, anthracenealdehyde phenylhydrazone; phosphamidophenols; phosphamidoanilines; polyhydroxybenzenes (for example, hydroquinone, t-butylhydroquinone, isopropylhydroquinone, and (2,5-dihydroxy-phenyl)methylsulfone); sulfydroxamic acids (for example, benzenesulfhydroxamic acid); sulfonamidoanilines (for example, 4-(N-methanesulfonamide)aniline); 2-tetrazolylthiohydroquinones (for example, 2-methyl-5-(1-phenyl-5-tetrazolylthio)hydroquinone); tetrahydroquionoxalines (for example, 1,2,3,4-tetrahydroquinoxaline); amidoxines; azines (for example, combinations of aliphatic carboxylic acid arylhydrazides with ascorbic acid); combinations of polyhydroxybenzenes and hydroxylamines, reductones and/or hydrazine; hydroxamic acids; combinations of azines with sulfonamidophenols; α-cyanophenylacetic acid derivatives; combinations of bis-β-naphthol with 1,3-dihydroxybenzene derivatives; 5-pyrazolones, sulfonamidophenol reducing agents, 2-phenylindane-1,3-dione, etc.; chroman; 1,4-dihydropyridines (for example, 2,6-dimethoxy-3,5-dicarboethoxy-1,4-dihydropyridine); bisphenols (for example, bis(2-hydroxy-3-t-butyl-5-methylphenyl)methane, bis(6-hydroxy-m-tri)mesitol, 2,2-bis(4-hydroxy-3-methylphenyl)propane, 4,5-ethylidene-bis(2-t-butyl-6-methyl)phenol, UV-sensitive ascorbic acid derivatives and 3-pyrazolidones. Of these, particularly preferred reducing agents are hindered phenols.

Oxidizing Agent

The photothermographic material in the invention preferably contains oxidizing agents. Oxidizing agents usable in the invention may be any one as long as it is capable of reducing fogging caused during storage. Preferred examples of oxidizing agents are described in JP-A 50-119624, 50-120328, 51-121332, 54-58022, 56-70543, 56-99335, 59-90842, 61-129642, 62-129845, 6-208191, 7-5621, 7-2781, 8-15809; U.S. Pat. Nos. 5,340,712, 5,369,000, 5,464,737, 3,874,946, 4,756,999, 5,340,712; European Patent Nos. 605981A1, 622666A1, 631176A1; JP-B 54-165, 7-2781; U.S. Pat. Nos. 4,180,665 and 4,442,202. Specifically, polyhalogenide compounds are preferred.

In the invention, the oxidizing agent is incorporated preferably in an amount of 1×10⁻⁴ to 1 mole, and more preferably 1×10⁻³ to 0.5 mole per mol of silver.

It is preferred to incorporate a fatty acid or its derivatives into at least one layer on the image forming layer side of the photothermographic material. Examples of fatty acids include lauric acid, myristic acid, palmitic acid, stearic acid, behenic acid, oleic acid, linoleic acid, linolenic acid and elaidic acid; and examples of fatty acid esters include butyl stearate, amyl stearate, octyl stearate, butyl palmitate, butyl myristate, butoxyethyl stearate, oleyl olate and butoxyethyl stearate.

It is preferred that the contrast-increasing agent is contained in a layer on the image forming layer side of the photothermographic material. The contrast-increasing agent is preferably a vinyl compound or a hydrazine compound. Examples of the vinyl compound include compounds 1-1 through 92-5 described in paragraph Nos. [0084] through [0103] of Japanese Patent O.P.I. Publication No. 2002-23300. Examples of the hydrazine compound include compounds H-1 through H-12 described in paragraph Nos. [0054] and [0055], and compounds H-1-1 through H-4-2 described in paragraph Nos. [0067] through [0071] of Japanese Patent O.P.I. Publication No. 2002-23300.

The above described components may be contained in at least one layer of one or more image forming layers of the photothermographic material of the invention. The components may be contained in the same image forming layer, or may be contained in different image forming layers, provided that they are not contained in the same image forming layer.

Support

Supports used for the photothermographic materials include, for example, paper, polyethylene-laminated paper, polypropylene-laminated paper, parchment, cloth, sheets or foils of metals (e.g., aluminum, copper, magnesium, zinc, etc.), glass, glass coated with metals (such as chromium alloy, steal, silver, gold, platinum, etc.) and plastic resin films. Examples of plastic resin used as a support include polyalkyl methacrylate (e.g., polymethyl methacrylate), polyesters (e.g., polyethylene terephthalate), polyvinyl acetal, polyamides (e.g., nylon), and cellulose esters (e.g., cellulose nitrate, cellulose acetate, cellulose, acetate-propionate, cellulose acetate-butyrate, etc.). The support may be coated with polymers, including polyvinylidene chloride, acrylic acid type polymers (e.g., polyacrylonitrile, polymethyl acrylate), polymers of unsaturated carboxylic acids (e.g., itaconic acid, acrylic acid), carboxymethyl cellulose and polyacrylamide. Copolymers may also be used. Instead of polymer coating, there may be provided a subbed layer containing a polymer. It is effective to subject the support to an annealing treatment under a relatively low tension to enhance its dimensional stability. For example, there may be optionally combined known techniques described in JP-B no. 60-22616, U.S. Pat. No. 2,779,684, Research disclosure No. 19809, JP-A Nos. 8-211547, 10-10676, 10-10677, 11-47676, 11-65025, 11-138628, 11-138648, 11-221892, 11-333922, and 11-333923. The tension applied to the support at the time of thermal treatment, and preferably at the time of subbing layer coating is preferably 0.4 to 80 N/cm², more preferably 2 to 60 N/cm², and still more preferably 10 to 50 N/cm². The thermal treatment temperature or drying temperature is preferably 70 to 220° C., more preferably 80 to 200° C., and still more preferably 90 to 190° C. Thermal treatment time at drying time is preferably 1 to 30 min., more preferably 2 to 20 min., and still more preferably 3 to 15 min.

One preferred embodiment of the layer arrangement of the invention is that a subbing layer is provided on one side of a support, thereon is provided an image forming layer, and further thereon is provided a surface protective layer. The subbing layer (of the image forming layer side) is preferably comprised of at least two layers, and the total dry thickness of the subbing layer is preferably 0.2 to 5 μm, and more preferably 0.5 to 3 μm. The dry thickness of the image forming layer is preferably 5 to 13 μm, and more preferably 7 to 11 μm. The dry thickness of the surface protective layer is preferably 2 to 10 μm, and more preferably 4 to 8 μm. The surface protective layer preferably contains a matting agent. The mean particle size of the matting agent is preferably 1 to 10 μm, and more preferably 3 to 7 μm. Commonly known fillers are usable as a matting agent and the use of powdery organic compounds such as polymethyl methacrylate is preferable.

It is also preferred that a subbing layer be provided on the opposite side of the support to the image forming layer, thereon be provided a backing layer, and further thereon be provided a backing layer-protective layer. The subbing layer (of the backing layer side) is preferably comprised of at least two layers and the layer closest to the support preferably is an antistatic layer containing a electrically conductive metal oxide and/or polymer. The conductive metal oxide is preferably SnO₂ which has been surface-treated with Sb and the conductive polymer is preferably a polyaniline. The total dry thickness of the subbing layer is preferably 0.2 to 4 μm, and more preferably 0.5 to 2 μm. The dry thickness of the backing layer is preferably 2 to 10 μm, and more preferably 4 to 8 μm. The backing layer preferably contains an antilialation dye. The dry thickness of the backing layer-protective layer is preferably 2 to 10 μm, and more preferably 4 to 8 μm. The backing layer-protective layer preferably contains matting agents. Commonly known fillers are usable as a matting agent and the use of powdery organic compounds such as polymethyl methacrylate is preferable. The mean particle size of the matting agent is preferably 1 to 10 μm, and more preferably 3 to 7 μm. The present invention can be effectively achieved by application of the foregoing layer arrangement and dry layer thickness.

Exposure of photothermographic materials used in the invention can be conducted preferably using an infrared laser at wavelengths of 700 to 1000 nm. After, exposure, thermal processing can be conducted by ultra-rapid access of not more than 45 sec. The thermal processing time, i.e., “top to top” is preferably 5 to 40 sec., and more preferably 5 to 30 sec. The expression “top to top” refers to a time from the time when the top of the photothermographic material is introduced into a film-insertion portion of a thermal processing machine to the time when the top comes out of the thermal processing machine. In one preferred embodiment of the invention, the transport speed in the thermal processing machine is 22 to 40 mm/sec.

As described above, it is expected that the mask material, which is prepared by exposing and thermally developing the photothermographic material described of the invention, minimizes fogging during storage, is resistant to scratches and does not produce exposure unevenness, when the PS plate is exposed through the mask material, and provides image portions difficult to be removed even when the mask material is fixed with an adhesive tape on a PS plate and the adhesive tape is peeled from the mask material.

### EXAMPLES

The present invention will be explained in the following examples, but is not limited thereto.

### Example 1

### Preparation of Subbed PET Support 1

Both surfaces of a biaxially stretched thermally fixed 125 μm polyethylene terephthalate (hereinafter, also denoted simply as PET) film were subjected to a plasma treatment 1 under the condition described below. Onto the surface of one side, the subbing coating composition a-1 descried below was applied so as to form a dried layer thickness of 0.8 μm, which was then dried. The resulting coating was designated Subbing Layer A-1. Onto the opposite surface, the subbing coating composition b-1 described below was applied to form a dried layer thickness of 0.8 μm. The resulting coating was designated as Subbing Layer B-1. Both subbing layer surfaces were each subjected to plasma treatment 2 under the condition described below.

Plasma Treatment Condition

Using a batch type atmospheric plasma treatment apparatus (AP-1-H-340, available from E. C. Chemical Co., Ltd.), plasma treatment 1 and plasma treatment 2 were each conducted at a high frequency output of 4.5 kW and a frequency of 5 kHz over a period of 5 sec. in an atmosphere of argon, nitrogen and hydrogen in a ratio of 90%, 5% and 5% by volume, respectively.

| | | |
|---|---|---|
| Subbing Coating Composition a-1 | | |
| Latex solution (solid 30%) of | 270 | g |
| a copolymer consisting of butyl acrylate | | |
| (30 weight %), t-butyl acrylate (20 weight %) | | |
| styrene (25 weight %) and 2-hydroxy | | |
| ethyl acrylate (25 weight %) | | |
| Hexamethylene-1,6-bis(ethyleneurea) | 0.8 | g |
| Polystyrene fine particles | 0.05 | g |
| (av. particle size, 3 μm) | | |
| Colloidal silica (av. particle size, 90 μm) | 0.1 | g |
| Water was added to make a 1 liter solution. | | |
| Subbing Coating Composition b-1 | | |
| Tin oxide doped with 0.1% by weight indium | 0.26 | g/m² |
| having an average particle size of 36 nm | | |
| Latex liquid (solid portion of 30%) | 270 | g |
| of a copolymer consisting of butyl acrylate | | |
| (30 weight %), styrene (20 weight %), and | | |
| glycidyl acrylate (40 weight %) | | |
| Hexamethylene-1,6-bis(ethyleneurea) | 0.8 | g |
| Water was added to make a 1 liter solution. | | |

Thermal Treatment of Support

The thus subbed support was heated at a temperature of 140° C. in the sublayer-drying process and gradually cooled, while being transported at a tension of 1×10⁵ Pa.

Preparation of Subbed PET Support 2

Both surfaces of a biaxially stretched thermally fixed 125 μm PET film were subjected to a plasma treatment 1 under the condition described above. Onto the surface of one side, the subbing coating composition a-2 descried below was applied so as to form a dried layer thickness of 0.8 μm, which was then dried. The resulting coating was designated Subbing Layer A-2. Onto the opposite surface, the subbing coating composition b-2 described below was applied to form a dried layer thickness of 0.8 μm. The resulting coating was designated as Subbing Layer B-2. Both subbing layer surfaces were each subjected to plasma treatment 2 described above.

| Subbing Coating Composition a-2 | | |
|---|---|---|
| Latex solution (solid 30%) of | 270 | g |
| a copolymer consisting of butyl acrylate | | |
| (30 weight %), t-butyl acrylate (20 weight %) | | |
| styrene (25 weight %) and 2-hydroxy | | |
| ethyl acrylate (25 weight %) | | |
| Hexamethylene-1,6-bis(ethyleneurea) | 0.8 | g |
| Water was added to make a 1 liter solution. | | |
| Subbing Coating Composition b-2 | | |
| Latex liquid (solid portion of 30%) | 270 | g |
| of a copolymer consisting of butyl acrylate | | |
| (30 weight %), styrene (20 weight %), and | | |
| glycidyl acrylate (40 weight %) | | |
| Hexamethylene-1,6-bis(ethyleneurea) | 0.8 | g |

Water was added to make a 1 liter solution.

Back Layer-side Coating

The following back layer coating solution 1 and the following backing protective layer coating solution 1 were each filtered using a filter of an absolute filtration accuracy of 20 μm, then, simultaneously coated on the antistatic subbing layer B-1 or B-2 of the support prepared above at a coating speed of 120 m/min so as to form a total wet thickness of 30 μm, and dried at 60° C. for 4 min.

Back Layer Coating Solution 1

| | | |
|---|---|---|
| Methyl ethyl ketone | 16.4 | g/m² |
| Polyester resin (Vitel PE2200B, | 106 | mg/m² |
| available from Bostic Co.) | | |
| Infrared dye-C | 37 | mg/m² |
| Stabilizing agent B-1 (Sumirizer BPA, | 20 | mg/m² |
| available from Sumitomo Chemical Co., Ltd.) | | |
| Stabilizing agent B-2 (Tomisoap 77, | 20 | mg/m² |
| available from Yoshitomi Seiyaku Co., Ltd.) | | |
| Cellulose acetate-propionate (CAP504-0.2, | 1.0 | g/m² |
| available from Eastman Chemical Co.) | | |
| Cellulose acetate-butylate (CAB381-20, | 1.0 | g/m² |
| available from Eastman Chemical Co.) | | |

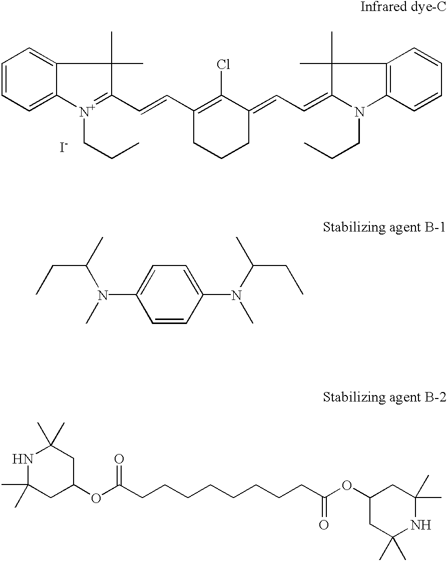 Backing Protective Layer Coating Solution 1

| | | |
|---|---|---|
| Methyl ethyl ketone | 22 | g/m² |
| Polyester resin (Vitel PE2200B, | 106 | mg/m² |
| available from Bostic Co.) | | |
| Antistatic agent (CH₃)₃SiO—[(CH₃)₂SiO]₂₀— | 22 | mg/m² |
| [CH₃SiO{CH₂CH₂CH₂O(CH₂CH₂O)₁₀— | | |
| (CH₂CH₂CH₂O)₁₅CH₃}]₃₀—Si(CH₃)₃ | | |
| Fluorine-containing surfactant F-1: C₈F₁₇SO₃Li | 10 | mg/m² |
| Cellulose acetate-propionate (CAP504-0.2, | 1.0 | g/m² |
| available from Eastman Chemical Co.) | | |
| Cellulose acetate-butylate (CAB381-20, | 1.0 | g/m² |
| available from Eastman Chemical Co.) | | |
| Matting agent (SILOID74, av. particle size | 5 | mg/m² |
| of 7 μm, available from Fuji-Davison Co.) | | |

3. Preparation of Image Forming Layer

Preparation of Silver Halide Emulsion A

In 700 ml of water were dissolved 22 g of phthalated gelatin, and 30 mg of potassium bromide. After adjusting the temperature and the pH to 40° C. and 5.0, respectively, 159 ml of an aqueous solution containing 18.6 g silver nitrate and 159 ml of an aqueous equimolar potassium bromide solution were simultaneously added by the controlled double jet addition in 10 minutes. Then, 476 ml of an aqueous solution containing 55.4 g of silver nitrate and an aqueous solution containing 1 mol/l of potassium bromide and 8×10⁻⁶ mol/l of K₃[IrCl₆]³⁻ were added by the double jet addition in 15 min. Then the emulsion was adjusted to pH 5.9 and pAg 8.0. There were obtained non-monodisperse, cubic silver halide grains having an average grain size of 0.08 μm, a grain size dispersity of 45%, and a proportion of the {100} face of 40%.

The thus obtained silver halide grain emulsion was heated to 60° C., and 8.5×10⁻⁵ mol per mol of silver of sodium thiosulfate, 1.1×10⁻⁵ mol per mol of silver of 2,3,4,5,6-pentafluorophenyldiphenylphosphin selenide, 1×10⁻⁶ mol per mol of silver of tellurium compound-1, 3.3×10⁻⁶ mol per mol of silver of chloroauric acid, 2.3×10⁻⁴ mol per mol of silver of thiocyanic acid were added, and the emulsion was ripened. Thereafter, the temperature was maintained at 50° C., 8×10⁻⁴ mol per mol of silver of sensitizing dye C were added while stirring, and 3.5×10⁻² mol of potassium iodide were further added. The resulting emulsion was rapidly cooled to 30° C. to obtain silver halide grain emulsion A.

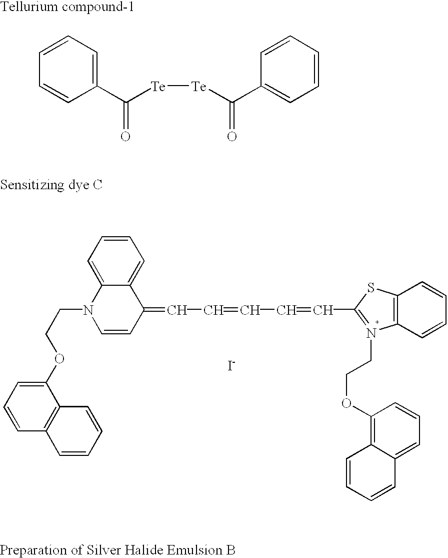

In 700 ml of water were dissolved 22 g of phthalated gelatin, and 30 mg of potassium bromide. After adjusting the temperature and the pH to 40° C. and 5.0, respectively, 159 ml of an aqueous solution containing 18.6 g silver nitrate and an aqueous potassium bromide solution were simultaneously added in 10 minutes by the controlled double jet addition while maintaining at pAg 7.7. Then, 476 ml of an aqueous solution containing 55.4 g of silver nitrate and an aqueous solution containing 1 mol/l of potassium bromide and 8×10⁻⁶ mol/l of K₃[IrCl₆]³⁻ were added in 30 minutes by the controlled double jet addition while maintaining at pAg 7.7. Then the emulsion was adjusted to pH 5.9 and pAg 8.0. There were obtained monodisperse, cubic silver halide grains having an average grain size of 0.08 μm, a grain size dispersity of 15%, and a proportion of the {100} face of 85%.

The thus obtained silver halide grain emulsion was heated to 60° C., and 8.5×10⁻⁵ mol per mol of silver of sodium thiosulfate, 1.1×10⁻⁵ mol per mol of silver of 2,3,4,5,6-pentafluorophenyldiphenylphosphin selenide, 2×10⁻⁶ mol per mol of silver of tellurium compound-1, 3.3×10⁻⁶ mol per mol of silver of chloroauric acid, 2.3×10⁻⁴ mol per mol of silver of thiocyanic acid were added, and the emulsion was ripened for 120 min. Thereafter, the temperature was maintained at 50° C., 8×10^{31 4} mol of sensitizing dye C were added while stirring, and 3.5×10⁻² mol of potassium iodide were further added. The resulting emulsion was rapidly cooled to 30° C. to obtain silver halide grain emulsion B.

Preparation of Organic Silver Salt Dispersion A

Behenic acid of 40 g, 7.3 g of stearic acid and 500 ml distilled water were mixed for 15 minutes at 90° C., and 187 ml of a 1 mol/l NaoH aqueous solution were added in 15 minutes with vigorous stirring, and 61 ml of a 1 mol/l silver nitrate aqueous solution were further added, and the temperature was lowered to 50° C. Subsequently, 124 ml of a 1 mol/l silver nitrate aqueous solution was added thereto and stirred for 5 minutes. The resulting solution was filtered using a suction funnel to obtain a solid product, and the solid product was subjected to water washing until the conductivity of the filtrate reached 30 μS/cm. The thus obtained solid was treated in a wet cake form, without being dried. To the wet cake equivalent to 34.8 g of dried solid, 12 g of polyvinyl alcohol and 150 ml of water were added and mixed to obtain slurry. The resulting slurry and 840 g of zirconia beads with an average diameter of 0.5 mm were placed in a vessel, and dispersed for 30 minutes employing a dispersing machine 1/4G sand grinder mill (produced by IMEX Co. Ltd.) to obtain organic silver salt dispersion A. The thus obtained organic silver salt dispersion A was comprised of non-disperse organic silver salt grains having a volume average grain size of 1.6 μm, and a grain size dispersity of 55%. The grain size was measured using Master Sizer X, available from Malvern Instrument Ltd.

Preparation of Organic Silver Salt Dispersion B

Behenic acid of 40 g, 7.3 g of stearic acid and 500 ml distilled water were mixed for 15 minutes at 90° C., and 187 ml of a 1 mol/l NaoH aqueous solution were added in 15 minutes with vigorous stirring, and 61 ml of a 1 mol/l silver nitrate aqueous solution were further added, and the temperature was lowered to 50° C. Subsequently, 124 ml of a 1 mol/l silver nitrate aqueous solution was added thereto and stirred for 30 minutes. The resulting solution was filtered using a suction funnel to obtain a solid product, and the solid product was subjected to water washing until the conductivity of the filtrate reached 30 μS/cm. The thus obtained solid was treated in a wet cake form, without being dried. To the wet cake equivalent to 34.8 g of dried solid, 12 g of polyvinyl alcohol and 150 ml of water were added and mixed to obtain slurry. The resulting slurry and 840 g of zirconia beads with an average diameter of 0.5 mm were placed in a vessel, and dispersed for 4 hours employing a dispersing machine 1/4G sand grinder mill (produced by IMEX Co. Ltd.) to obtain organic silver salt dispersion B. The thus obtained organic silver salt dispersion B was comprised of monodisperse organic silver salt grains having a volume average grain size of 1.2 μm, and a grain size dispersity of 20%. The grain size was measured using Master Sizer X. To the dispersion were added 3 ml of a methanol solution containing 6% of phenylbromide perbromide. When the dispersion was observed through an electron microscope, silver halide grains with a grain size of less than 0.01 μm were observed.

Preparation of Another Solid Particle Dispersion

Tetrachlorophthalic acid, 4-methylphthalic acid, 1,1-bis(2-hydroxy-3,5-dimethylphenyl)-3,5,5-trimethylhexane, phthalazine, and tribromomethylsulfonylbenzene each were dispersed according to the following method to prepare the respective solid particle dispersions.

To 5.4 g of tetrachlorophthalic acid were added 0.81 g of hydroxypropyl cellulose and 94.2 ml of water with stirring to obtain slurry, and allowed to stand for 10 hours. The slurry was placed in a vessel together with 360 g of zirconia beads having an average diameter of 0.5 mm and dispersed for 5 hours employing the same dispersing machine as employed in the preparation of the above organic silver salt dispersions to obtain a solid particle dispersion of the tetrachlorophthalic acid, 70% by weight of which was accounted for by particles having a size of not more than 1.0 μm. The solid particle dispersions of the other compounds were prepared optionally by varying the amount of a dispersant or dispersing time to obtain an intended average particle size.

4. Preparation of coating solutions

(Preparation of Image Forming Layer Coating Solution A)

The following components were added to the organic silver salt dispersion A prepared above to obtain Image

Forming Layer Coating Solution A.

| | | |
|---|---|---|
| Organic silver salt dispersion A | 1 | mol |
| Silver Halide Emulsion A | 0.05 | mol |
| Binder, SBR latex LACSTAR 3307B | 430 | g |
| (available from DAINIPPON INK & | | |
| CHEMICALD Inc.) | | |
| Tetrachlorophthalic acid | 5 | g |
| 1,1-Bis(2-hydroxy-3,5-dimethylphenyl)- | 98 | g |
| 3,5,5-trimethylhexane | | |
| Phthalazine | 9.0 | g |
| Tribromomethysulfonylbenzene | 12 | g |
| 4-Methylphthalic acid | 7 | g |
| Vinyl Compound-1 | 8 | g |
| Hydrazine Derivative-1 | 5 | g |

LACSTAR 3307B is latex of styrene-butadiene copolymer, in which the average size of the particles is from 0.1 to 0.15 μm, and the equilibrium moisture content is 0.6% at 25° C. and 60% RH.

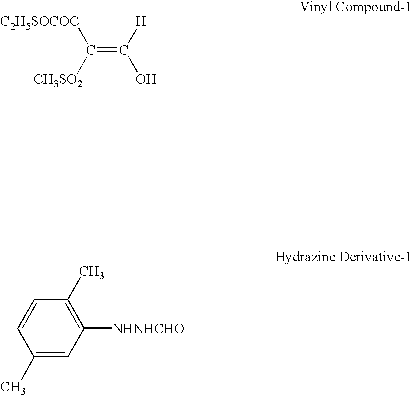

(Preparation of Image Forming Layer Coating Solution B)

The following components were added to the organic silver salt dispersion B prepared above to obtain Image

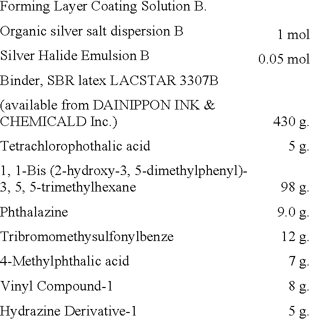

Preparation of Surface protective layer coating Solution 1

To 500 g of 40% Binder resin B were added 262 g of water and then, 14 g of benzyl alcohol as a film-forming auxiliary, 2.5 g of Compound D, 2.5 g of Cellosol 524 (produced by Chuukyo Ushi Co., Ltd.), 12 g of Compound E, 1 g of Compound F, 2 g of Compound G, 7.5 g of Compound H, 0.5 g of polymethyl methacrylate particles having an average particle size of 3 μm as a matting agent were added in that order. Water was added thereto to make a 1000 g solution. Thus, Surface protective layer coating Solution 1 was prepared which had a pH of 4.5 and a viscosity at 25° C. of 5 cp.

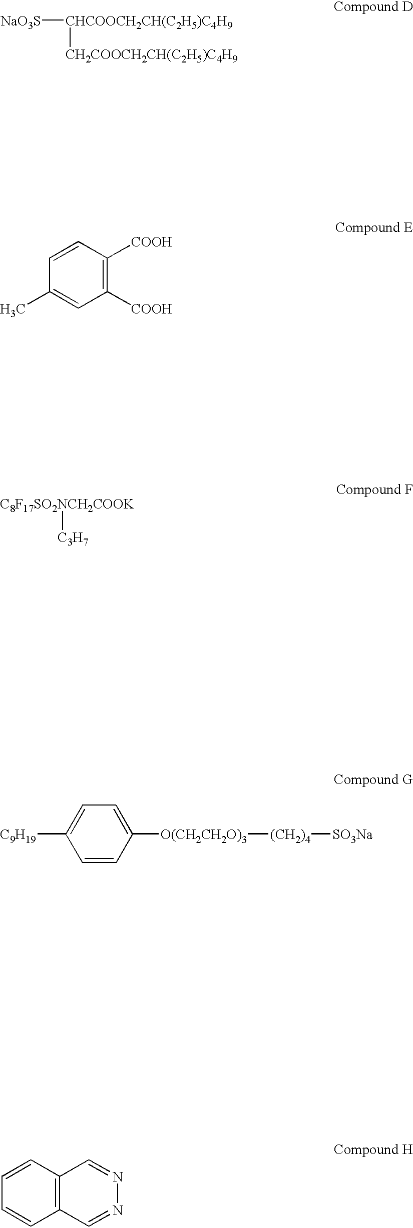

Binder resin B: polyurethane having a cyclohexane ring containing —SO₃Na (being made from diphenylmethanediisocyanate/neopentyl glycol/ethylene glycol/cylohexyldimethanol/isophthalic acid/phthalic acid=11/22/3/22/29/13, by weight ratio and exhibiting Tg=73° C.; commercial name UR-8200, product by TOYOBO Co., Ltd.)

Preparation of Surface protective layer coating Solution 2

To 500 g of 40% Binder resin E were added 262 g of water and then, 14 g of benzyl alcohol as a film-forming auxiliary, 2.5 g of Compound D, 3.6 g of Cellosol 524 (produced by Chuukyo Ushi Co., Ltd.), 12 g of Compound E, 1 g of Compound F, 2 g of Compound G. 7.5 g of Compound H, 0.5 g of monodisperse silica particles having a variation coefficient of 20% (an average particle size of 3.5 μm) as a matting agent, 0.5 g of monodisperse polymer (Exemplified Compound P-5) particles having a variation coefficient of 15% (an average particle size of 5 μm) as a matting agent, and 1 g of colloidal silica were added in that order. Water was added thereto to make a 1000 g solution. Thus, Surface protective layer coating Solution 2 was prepared which had a pH of 3.4 and a viscosity at 25° C. of 5 cp.

Binder resin E: polymer latex (methyl methacrylate/styrene/2-hexylethyl acrylate/2-hydroxyethyl methacrylate/methacrylic acid=59/9/26/5/1 by weight ratio and exhibiting Tg=47° C.)

5. Preparation of Photothermographic Material Sample

Preparation of Sample No. 101

The foregoing image forming layer coating solution A and surface protective layer coating solution 1 were each filtered by allowing to pass through a filter having an absolute filtration accuracy of 20 μm, and the resulting image forming layer coating solution A and surface protective layer coating solution 1 were ejected from slits of an extrusion type die coater and simultaneously coated in that order on Subbing Layer A-2 of the PET Support 2 at a coating speed of 90 m/min. After 8 sec., the thus coated sample was dried using hot air of a dry bulb temperature of 75° C. and a dew point of 10° C. over a period of 5 min. and wound up on a roll at a tension of 196 N/m (or 20 kg/m) at an atmosphere of 23° C. and 50% RH to obtain photothermographic material sample No. 101. The resulting sample had a silver coating amount of 1.5 g/m² and a dry thickness of 2.5 μm.

After coating and drying, silver halide grains in this Sample 101 were observed by an electron microscope. As a result of electron microscopic observation of 500 silver halide grains, no grains of less than 0.01 μm were observed in Sample 101.

Preparation of Sample No. 102

The image forming layer coating solution B and surface protective layer coating solution 2, which were not filtered, were ejected from slits of an extrusion type die coater, and simultaneously coated in that order on Subbing Layer A-1 of the PET Support 1 at a coating speed of 90 m/min. After 8 sec., the thus coated sample was dried using hot air of a dry bulb temperature of 30° C. and a dew point of 10° C. over a period of 15 min., and wound up on a roll at a tension of 196 N/m (or 20 kg/m) at an atmosphere of 23° C. and 50% RH to obtain photothermographic material sample No. 102. The resulting sample had a silver coating amount of 1.5 g/m² and a dry thickness of 2.5 μm. The Vickers hardness of the surface of the image forming layer side was 110.

After coating and drying, silver halide grains in this Sample 102 were observed by an electron microscope. As a result of electron microscopic observation of 500 silver halide grains, silver halide grains of less than 0.01 μm were observed in Sample 102 and grains of less than 0.01 μm were 50% of the total number of silver halide grains.

6. Exposure of samples

The image forming layer-side of each of the above obtained samples was exposed through an optical wedge to laser using an exposure apparatus having a light source in which a 780 nm semiconductor laser was made to longitudinally multiple modes using the high frequency superimposing method.

7. Thermal development

Employing a thermal developing machine having the structure as shown in FIG. 2, the exposed sample No. 101 was preheated at 105° C. for 20 seconds, and then subjected to thermal development at 120° C. for 20 seconds to obtain a mask material sample 101, in which the transport speed of the sample was 28 mm/sec. The exposed sample No. 102 was subjected to thermal development in the same manner as the exposed sample No. 101 to obtain a mask material sample 102, except that a thermal developing machine having the structure as shown in FIG. 3 was employed in which the transport speed of the sample was 20 mm/sec.

(Rate of thermal dimensional change)

Each sample was allowed to stand at 23° C. and 50% RH for not less than 2 hours, and the four crosses “+” were marked, through a knife, at the four verteces of a square with a side of 10 cm on the sample surface so that one diagonal connecting two opposite verteces was in accordance with the longitudinal direction and the other diagonal connecting the other two verteces was in accordance with the transverse direction. The length of the diagonals (before thermal treatment) was measured. Thereafter, the sample was subjected to heat treatment, allowed to stand at 23° C. and 50% RH for not less than 2 hours, and then, the length of the diagonals (after thermal treatment) was measured. The difference between the length of the diagonals before the heat treatment and that after the heat treatment was divided by the length of the diagonal before heat treatment and multiplied by 100 to obtain rate of thermal dimensional change (%). Rate of thermal dimensional change greater of those in the longitudinal and transverse directions was adopted for evaluation. In the heat treatment, the sample was inserted between the two aluminum sheets (in the form of a square with a side of 15 cm) with a thickness of 3 mm, which had been in advance placed in a 120° C. oven, heated in the oven for 20 seconds, and cooled. The length was measured employing a measurescope20, DP-200, SC-102 produced by Nikon Co., Ltd.

Rate of thermal dimensional change of sample No. 101 was 0.005%, and rate of thermal dimensional change of sample No. 102 was 0.055%.

Measurement of characteristic values and evaluation thereof (Measurement of the maximum surface roughness of the protective layer surface on the image forming layer side of the photothermographic material sample)

With respect to the photothermographic material sample before and after heat treatment, the maximum surface roughness (Rt) of the protective layer surface on the image forming layer side was measured according to the following method:

The maximum surface roughness (Rt) was measured at an area of 368 μm×238 μm employing a non-contact three dimensional surface roughness measuring device RST/PLUS (produced by WYKO Co., Ltd.). Rt herein referred to is as defined in JIS Surface Roughness (B0601). Describing one hundred squares with a side of 3 cm on the sample with a size of 30 cm×30 cm, Rt was measured at the center of each of the squares, and the average of the measurements was computed.

Herein, the heat treatment was carried out preheating a photothermographic material sample at 115° C. for 15 seconds and then heating the resulting sample at 120° C. for 15 seconds.

The maximum surface roughness of the protective layer surface on the image forming layer side of the photothermographic material sample before the heat treatment, the maximum surface roughness of the protective layer surface on the image forming layer side of the photothermographic material sample after the heat treatment, and the variation between them are shown in Table 1.

(Measurement of fog density after storage)

Each sample was stored at 50° C. for 3 days, subjected to thermal development, in which the sample was preheated at 105° C. for 20 seconds and then heated at 120° C. for 20 seconds, for evaluation for storage stability. Transmission density to UV at the unexposed portions of the resulting developed sample was measured employing an optical densitometer through a filter which shielded light of a wavelength of not shorter than 420 nm. In the invention, the density was measured according to the ultraviolet mode of an optical densitometer, X-Rite 361T, produced by X-Rite Co., Ltd. The results are shown in Table 1. Samples exhibiting a fog density of not less than 0.25 cannot be put into practical use.

(Scratches occurring on the developed sample when used on imagewise exposure of PS plates)

Each of the mask material samples obtained above by thermal development employing the thermal developing machines above was placed under vacuum contact with a negative working PS plate SWN-X (produced by Konica Corporation) for 60 seconds employing a printing plate maker, and then the PS plate was imagewise exposed. Employing the same mask sample, ten PS plates were exposed in the same manner as above. After the ten PS plates were exposed, scratches on the mask sample used in the exposure of the PS plates were observed, and evaluated in terms of ranks 1 to 5. No scratches were rated as rank 5. As the number or size of scratches increases, the ranking was lowered. A sample providing a rank of not more than 2 was judged as impracticable.

(Influence of density unevenness of developed photothermographic material sample on printed images)

A photothermographic material sample was exposed through a screen tint with a 50% dot area, and then subjected to thermal development in the same manner as in photothermographic material sample 101 above to obtain a mask material for PS plates. The mask material was cut into a size of 25 cm×30 cm, and allowed to stand at 23° C. and 50% RH for one hour. The resulting mask material was placed under vacuum contact with a negative working PS plate SWN-X (produced by Konica Corporation) for 10 seconds employing a printing plate maker, and then the PS plate was imagewise exposed with a metal halide lamp. The exposed plate was developed with a developing solution in which a developer SDN-21 (produced by Konica Corporation) for a negative working PS plate was diluted with water by a factor of 4, washed with water, and dried to obtain a printing plate.

As a printing press, DAIYA 1F-1 produced by Mitsubishi Jukogyo Co., Ltd., was employed. Printing was carried out employing a coated paper, dampening water (H solution SG-51 with a concentration of 1.5%, produced by Tokyo Ink Co., Ltd.), and ink (Toyo King High Eco M (magenta), produced by Toyo Ink Co., Ltd.). An ink supply roller was brought into contact with the plate cylinder and dampening water was supplied to the printing plate for 10 seconds while the (cylinder was rotated, and then, ordinary printing was carried out. The dots of the resulting printed images were observed according to five criteria. No removal of dots was rated as rank 5. As dot removal was increased, rankink was lowered. A sample providing a rank of not more than 2 was judged as impracticable.

(Adhesive tape test)

A photothermographic material sample was exposed through a screen tint with a 50% dot area, and then thermally developed to obtain a mask material. A Sellotape (produced by Sekisui Co., Ltd.) with a width of 1 cm and a length of 15 cm was adhered to the surface layer on the image forming layer side of the mask material so as not to incorporate air between the Sellotape and the surface, and allowed to stand at 30° C. and 48% RH for one day. Thereafter, the Sellotape was peeled from the surface layer, and portions of the surface layer at which the Sellotape was peeled were observed. No removal of the surface layer was rated as rank 5. As the removed layer area was increased, the rank was lowered to 4, 3, 2, and 1 in that order. A sample providing a rank of not more than 2 was judged as impracticable.

The results are shown in Table 1.

TABLE 1

| | | Image | Surface | | | |
|---|---|---|---|---|---|---|
| | | forming | protective | Thermal | Rt before heat | Rt after heat |
| Sample No. | Support | layer | layer | development | treatment (μm) | treatment (μm) |
| 101 | 2 | A | 1 | | 3.7 | 3.5 |
| 102 | 1 | B | 2 | | 3.2 | 1.3 |

| | Difference | | | | | |
|---|---|---|---|---|---|---|
| | between | | | ** | | |
| | Rts before | | | Influence | | |
| | and after heat | Fog density | * | of density | Adhesive | |
| Sample No. | treatment (μm) | after storage | Scratches | unevenness | tape test | Remarks |
| 101 | 0.2 | 0.21 | 5 | 5 | 5 | Inv. |
| 102 | 1.9 | 0.32 | 2 | 2 | 2 | Comp. |

* Scratches occurring in the developed sample when used on imagewise exposure of PS plates
** Influence of density unevenness of developed photothermographic material sample on printed images
Inv.: Invention, Comp. : Comparative

As is apparent from Table 1 above, Inventive sample is superior in any of the evaluation to comparative sample.

### EFFECT OF THE INVENTION

The present invention provides a photothermographic material minimizing fogging during storage, a photothermographic material giving a mask material which is resistant to scratches and does not produce exposure unevenness, when the PS plate is exposed through the mask material, a photothermographic material giving a mask material in which image portions of the mask are difficult to be removed when the mask material is fixed with an adhesive tape on a PS plate and the adhesive tape is peeled from the mask material, and further provides a mask material with satisfactory performance which is prepared by forming an image on the photothermographic material described above.

What is claimed is:

1. A photothermographic material comprising a support and provided on one side of the support, one or more image forming layers containing a binder, an organic silver salt, silver halide, and a reducing agent, wherein the variation in the maximum surface roughness Rt of the surface on the image forming layer side between the materials before heat treatment and after heat treatment is not more than 1.5 μm.

2. The photothermographic material of claim 1, wherein when the material is subjected to heat treatment at 120° C. for 20 seconds, the absolute value of rate of thermal dimensional change in the longitudinal direction and the absolute value of rate of thermal dimensional change in the transverse direction both are from 0.001 to 0.04%.

3. The photothermographic material of claim 1, wherein at least one layer of the image forming layers contains a latex polymer in an amount of not less than 50% by weight based on the total weight of the binder contained in the at least one layer, and solvents used in coating solutions for coating the image forming layers contain water in an amount of not less than 30% by weight.

4. The photothermographic material of claim 1, wherein the photothermographic material is subjected to thermal development during which the material is transported while the surface on the image forming layer is brought into contact with rollers driven and the surface of the support opposite the image forming layer is brought into contact with a flat plane.

5. The photothermographic material of claim 4, wherein the photothermographic material is subjected to thermal development at a transporting speed of from 22 to 40 mm/second.

6. The photothermographic material of claim 1, wherein at least one layer on the image forming layer side further contains a matting agent of a polymer with a glass transition temperature of not less than 80° C.

7. The photothermographic material of claim 6, wherein the polymer is a polymer comprising monomer units represented by the following formulae A, B and C: 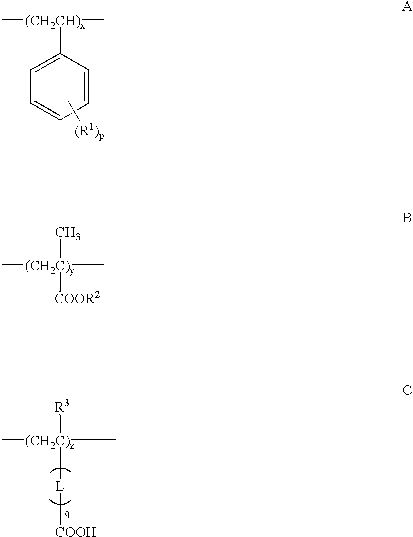
wherein R¹ represents a methyl group or a halogen atom; R² represents a methyl group or an ethyl group; R³ represents a hydrogen atom, a chlorine atom, or a methyl group, L represents a divalent linkage group; p represents an integer of from 0 to 2; q represents 0 or 1; x represents 3 to 60 mol %; y represents 30 to 96.5 mol %; and z represents 0.5 to 25 mol %.

8. The photothermographic material of claim 6, wherein at least one layer on the image forming layer side is an outermost layer on the image forming layer side.

9. The photothermographic material of claim 1, wherein at least one layer on the image forming layer side further an inorganic matting agent with an average particle size of from 0.1 to 10 μm.

10. The photothermographic material of claim 9, wherein at least one layer on the image forming layer side is an outermost layer on the image forming layer side.

11. A method of processing a photothermographic material, the method comprising the step of subjecting the material to thermal development, the material comprising a support and provided on one side of the support, one or more image forming layers containing a binder, an organic silver salt, silver halide, and a reducing agent, wherein the variation in the maximum surface roughness Rt of the surface on the image forming layer side between the materials before heat treatment and after heat treatment is not more than 1.5 μm.

12. The method of claim 11, wherein when the material is subjected to heat treatment at 120° C. for 20 seconds, the absolute value of rate of thermal dimensional change in the longitudinal direction and the absolute value of rate of thermal dimensional change in the transverse direction both are from 0.001 to 0.04%.

13. The method of claim 11, wherein at least one layer of the image forming layers of the photothermographic material contains a latex polymer in an amount of not less than 50% by weight based on the binders contained in the at least one layer, and solvents used in coating solutions for coating the image forming layers contain water in an amount of not less than 30% by weight.

14. The method of claim 11, wherein the thermal development is one in which the photothermographic material is transported while the surface on the image forming layer is brought into contact with rollers driven and the surface of the support opposite the image forming layers is brought into contact with a flat plane.

15. The method of claim 11, wherein the thermal development is carried out at a transporting speed of from 22 to 40 mm/second.

16. A mask material prepared by subjecting to thermal development a photothermographic material comprising a support and provided on one side of the support, one or more image forming layers containing a binder, an organic silver salt, silver halide, and a reducing agent, wherein the variation in the maximum surface roughness Rt of the surface on the image forming layer side between the materials before heat treatment and after heat treatment is not more than 1.5 μm.
